(19) United States
(12) Patent Application Publication
(10) Pub. No.: US 2023/0335676 A1
(43) Pub. Date: Oct. 19, 2023

(54) NANOROD LIGHT-EMITTING DIODE, DISPLAY APPARATUS INCLUDING THE NANOROD LIGHT-EMITTING DIODE, AND METHOD OF MANUFACTURING THE NANOROD LIGHT-EMITTING DIODE

(71) Applicant: SAMSUNG ELECTRONICS CO., LTD., Suwon-si (KR)

(72) Inventors: Youngchul LEEM, Uiwang-si (KR); Joosung KIM, Seongnam-si (KR); Younghwan PARK, Seongnam-si (KR); Dongchul SHIN, Suwon-si (KR); Jeongyub SEE, Yongin-si (KR); Junhee CHOI, Seongnam-si (KR)

(73) Assignee: SAMSUNG ELECTRONICS CO., LTD., Suwon-si (KR)

(21) Appl. No.: 17/960,531

(22) Filed: Oct. 5, 2022

(30) Foreign Application Priority Data
Apr. 18, 2022 (KR) 10-2022-0047775

(51) Int. Cl. H01L 33/24; H01L 33/00; H01L 33/12; H01L 33/38; H01L 33/44; H01L 27/15

(52) U.S. Cl. CPC H01L 33/24; H01L 33/007; H01L 33/12; H01L 33/38; H01L 33/44; H01L 27/156

(57) ABSTRACT

A nanorod light-emitting diode includes a first conductivity-type semiconductor layer including a body having a cylindrical shape, and a hexagonal pyramid shape provided on the body, an active layer covering an upper surface of the hexagonal pyramid shape, a second conductivity-type semiconductor layer covering an upper surface of the active layer, an electrode layer covering an upper surface of the second conductivity-type semiconductor layer, and an insulating layer formed to surround a side surface of the body and to expose a lower region of the side surface of the body.

### CROSS-REFERENCE TO RELATED APPLICATION

This application is based on and claims priority under 35 U.S.C. § 119 to Korean Patent Application No. 10-2022-0047775, filed on Apr. 18, 2022, in the Korean Intellectual Property Office, the disclosure of which is incorporated by reference herein in its entirety.

### BACKGROUND

### 1. Field

Embodiments of the disclosure relate to a nanorod light-emitting diode, a display apparatus including the nanorod light-emitting diode, and a method of manufacturing the nanorod light-emitting diode.

### 2. Description of the Related Art

As display apparatuses, a liquid crystal display (LCD), an organic light-emitting diode (OLED) display, a light-emitting diode (LED) display, and the like are widely used. Display apparatuses have been developed to increase resolution, and high resolution is realized by reducing the sizes of pixels. However, because the manufacturing cost of display apparatuses is very high when pixels are composed of LEDs, a nanorod light-emitting diode is applied to the pixels in order to lower the manufacturing cost. In addition, when all RGB colors for realizing a display apparatus are implemented with LEDs, colors may be implemented without a color filter, and thus, interest in nanorod light-emitting diodes is increasing.

A nanorod light-emitting diode may be manufactured using a top-down method or a bottom-up method. In a top-down method, a buffer layer, a semiconductor layer, an active layer, etc. are stacked on a substrate and then patterned to form a plurality of nanorod light-emitting diodes. On the other hand, in a bottom-up method, a substrate and a buffer layer are stacked and patterned to form a mold having a plurality of openings and a plurality of nanorod light-emitting diodes are provided respectively in the plurality of openings.

When a plurality of nanorod light-emitting diodes are formed by the top-down method, the half maximum widths, intensities, and main wavelengths of pieces of light respectively emitted from the plurality of nanorod light-emitting diodes formed at various points on the substrate may differ. In other words, in the case of the top-down method, it may be difficult to secure that a plurality of nanorod light-emitting diodes are produced uniformly on one substrate.

When a plurality of nanorod light-emitting diodes are formed by the bottom-up method, it is relatively easy to secure that the plurality of nanorod light-emitting diodes are uniform, compared to the top-down method. An existing bottom-up method may include a process of forming a buffer layer having a thick and complex structure on a substrate in order to reduce defects that may occur in the plurality of nanorod light-emitting diodes. In this case, process cost may increase.

### SUMMARY

Provided are a method of manufacturing a nanorod light-emitting diode, the method being capable of securing that a plurality of nanorod light-emitting diodes are uniform while reducing process cost by utilizing a nanoscale thin buffer layer, a nanorod light-emitting diode manufactured by the method, and a display apparatus including the nanorod light-emitting diode.

However, the above-described objective is an example, and is not limited thereto.

Additional aspects will be set forth in part in the description which follows and, in part, will be apparent from the description, or may be learned by practice of the presented embodiments of the disclosure.

According to an aspect of the disclosure, there is provided a nanorod light-emitting diode including: a first conductivity-type semiconductor layer including a body portion and a top portion provided on the body portion, the body portion having a cylindrical shape, and the top portion having a hexagonal pyramid shape; an active layer covering an upper surface of the top portion; a second conductivity-type semiconductor layer covering an upper surface of the active layer; an electrode layer covering an upper surface of the second conductivity-type semiconductor layer; and an insulating layer provided on a side surface of the body portion to cover a first region of the side surface of the body portion and not cover a second region of the side surface of the body portion, the second region being lower than the first region.

A height of the second region of the side surface of the body portion may be about 20 nm to about 100 nm.

A height of the body portion may be about 2 μm to about 7 μm.

A diameter of the body portion may be about 50 nm to about 1000 nm.

A first diameter of the body portion at the first region may be greater than a second diameter of the body portion at the second region.

The insulating layer may be in direct contact with the body portion at the first region.

Each of the first conductivity-type semiconductor layer and the second conductivity-type semiconductor layer may include InAlGaN, GaN, AlGaN, InGaN, AlN, InN, or a combination thereof.

According to another aspect of the disclosure, there is provided a nanorod light-emitting diode including: a first conductivity-type semiconductor layer including a body portion having a cylindrical shape; an active layer covering an upper surface of the first conductivity-type semiconductor layer and having a hexagonal column shape; a second conductivity-type semiconductor layer covering an upper surface of the active layer; an electrode layer covering an upper surface of the second conductivity-type semiconductor layer; and an insulating layer provided on a side surface of the body portion to cover a first region of the side surface of portion and not cover a second region of the side surface of the body portion, the second region being lower than the first region.

The insulating layer may be in direct contact with the body portion at the first region, a side surface of the active layer, a side surface of the second conductivity-type semiconductor layer, and a side surface of the electrode layer.

A height of the second region of the side surface of the body portion may be about 20 nm to about 100 nm.

According to another aspect of the disclosure, there is provided a method of manufacturing a nanorod light-emitting diode, the method including: sequentially stacking a buffer layer, an etch stop layer, an oxide layer, and an etch mask layer on a substrate; sequentially patterning the etch mask layer, the oxide layer, and the etch stop layer to form a plurality of openings that are spaced apart from each other and expose the buffer layer; forming a first conductivity-type semiconductor material layer by filling the plurality of openings and covering an upper surface of the oxide layer; forming a plurality of first conductivity-type semiconductor layers by patterning the first conductivity-type semiconductor material layer, each of the a plurality of first conductivity-type semiconductor layers having a nanorod shape; forming a plurality of active layers on the plurality of first conductivity-type semiconductor layers; forming a plurality of second conductivity-type semiconductor layers on the plurality of active layers; forming a plurality of electrode layers on the plurality of second conductivity-type semiconductor layers; removing the oxide layer; forming a plurality of insulating material layers on upper surfaces of the plurality of electrode layers and side surfaces of the plurality of first conductivity-type semiconductor layers; forming a plurality of insulating layers surrounding the side surfaces of the plurality of first conductivity-type semiconductor layers by patterning the plurality of insulating material layers to expose the upper surfaces of the plurality of electrode layers; and separating the plurality of first conductivity-type semiconductor layers from the buffer layer.

The buffer layer may have a thickness of about 5 nm to about 200 nm.

The buffer layer may include aluminum nitride.

The buffer layer may have a crystal orientation in a (002) direction.

The etch stop layer may include one of amorphous silicon and silicon oxide.

The etch stop layer may have a thickness of about 20 nm to about 100 nm.

The oxide layer may have a thickness of about 2 μm to about 6 μm.

The first conductivity-type semiconductor material layer may include gallium, and wherein, in the forming of the plurality of first conductivity-type semiconductor layers, the first conductive-type semiconductor material layer is formed at a process temperature of about 1100° C. to about 1500° C. such that a first diameter of a central region of each of the plurality of first conductivity-type semiconductor layers is greater than a second diameter of a lower region of each of the plurality of first conductivity-type semiconductor layers, the central region being surrounded by the oxide layer and the lower region being adjacent to the etch stop layer.

In the forming of the plurality of first conductivity-type semiconductor layers, the plurality of first conductivity-type semiconductor layers may be formed such that upper surfaces of the plurality of first conductivity-type semiconductor layers are higher than the upper surface of the oxide layer with respect to a reference plane parallel to the upper surface of the oxide layer.

According to another aspect of the disclosure, there is provided a method of manufacturing a nanorod light-emitting diode, the method comprising: sequentially stacking a buffer layer, an etch stop layer, an oxide layer, and an etch mask layer on a substrate; sequentially patterning the etch mask layer, the oxide layer, and the etch stop layer to form a plurality of openings that are spaced apart from each other and expose the buffer layer; forming a first conductivity-type semiconductor material layer by filling the plurality of openings and covering an upper surface of the oxide layer; forming a plurality of first conductivity-type semiconductor layers by patterning the first conductivity-type semiconductor material layer, each of the a plurality of first conductivity-type semiconductor layers having a nanorod shape; removing the oxide layer; forming a plurality of active layers on the plurality of first conductivity-type semiconductor layers; forming a plurality of second conductivity-type semiconductor layers on the plurality of active layers; forming a plurality of electrode layers on the plurality of second conductivity-type semiconductor layers; forming a plurality of insulating material layers on the plurality of electrode layers; forming a plurality of insulating layers surrounding side surfaces of the plurality of electrode layers by patterning the plurality of insulating material layers to expose upper surfaces of the plurality of electrode layers; and separating the plurality of first conductivity-type semiconductor layers from the buffer layer.

According to another aspect of the disclosure, there is provided a display apparatus including: a pixel array including a plurality of nanorod light-emitting diodes arranged in two dimensions; a scan driver configured to apply a scan signal to the pixel array; a data driver configured to apply a data signal to the pixel array; and a processor configured to control operations of the scan driver and the data driver, wherein each of the plurality of nanorod light-emitting diodes includes: a first conductivity-type semiconductor layer including a body portion having a cylindrical shape; an active layer covering an upper surface of the first conductivity-type semiconductor layer and having a hexagonal column shape; a second conductivity-type semiconductor layer covering an upper surface of the active layer; an electrode layer covering an upper surface of the second conductivity-type semiconductor layer; and an insulating layer provided on a side surface of the body portion to cover a first region of the side surface of the body portion and not cover a second region of the side surface of the body portion, the second region being lower than the first region.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view illustrating a configuration of a nanorod light-emitting diode according to an example embodiment;

FIG. 2 is a plan view of a first conductivity-type semiconductor layer and an active layer included in the nanorod light-emitting diode of FIG. 1;

FIG. 3 is a schematic cross-sectional view illustrating a configuration of a nanorod light-emitting diode according to another example embodiment;

FIG. 4 is a schematic cross-sectional view illustrating a configuration of a nanorod light-emitting diode according to another example embodiment;

FIG. 5 is a plan view of a first conductivity-type semiconductor layer and an active layer included in the nanorod light-emitting diode of FIG. 4;

FIG. 6 is a schematic cross-sectional view illustrating a configuration of a nanorod light-emitting diode according to another example embodiment;

FIG. 7 is a schematic cross-sectional view illustrating a configuration of a nanorod light-emitting diode according to another example embodiment;

FIG. 8 is a plan view of a first conductivity-type semiconductor layer and a second conductivity-type semiconductor layer included in the nanorod light-emitting diode of FIG. 7;

FIG. 9 is a schematic cross-sectional view illustrating a configuration of a nanorod light-emitting diode according to another example embodiment;

FIG. 10 is a flowchart illustrating a method of manufacturing a nanorod light-emitting diode, according to an example embodiment;

FIGS. 11 to 20 are views for explaining the method of manufacturing a nanorod light-emitting diode, which is illustrated in FIG. 10;

FIG. 21 is a view for explaining a method of manufacturing a nanorod light-emitting diode, according to another example embodiment;

FIG. 22 is a flowchart illustrating a method of manufacturing a nanorod light-emitting diode, according to another example embodiment;

FIGS. 23 to 26 are views for explaining the method of manufacturing a nanorod light-emitting diode, which is illustrated in FIG. 22;

FIG. 27 is a view for explaining a method of manufacturing a nanorod light-emitting diode, according to another example embodiment;

FIG. 28 is a flowchart illustrating a method of manufacturing a nanorod light-emitting diode, according to another example embodiment;

FIGS. 29 to 33 are views for explaining the method of manufacturing a nanorod light-emitting diode, which is illustrated in FIG. 28;

FIG. 34 is a schematic conceptual view of a display apparatus according to an example embodiment;

FIG. 35 is a schematic circuit diagram of a display apparatus according to an example embodiment;

FIG. 36 is a block diagram of an electronic device according to an example embodiment;

FIG. 37 illustrates an example in which a display apparatus according to an example embodiment is applied to a mobile device;

FIG. 38 illustrates an example in which a display apparatus according to an example embodiment is applied to a vehicle display apparatus;

FIG. 39 illustrates an example in which a display apparatus according to an example embodiment is applied to augmented reality glasses or virtual reality glasses;

FIG. 40 illustrates an example in which a display apparatus according to an example embodiment is applied to a signage; and

FIG. 41 illustrates an example in which a display apparatus according to an example embodiment is applied to a wearable display.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. In the drawings, a size or a thickness of each element in the drawings may be exaggerated for clarity and convenience of explanation. Embodiments described below are merely examples, and various modifications are possible from these embodiments.

Hereinafter, the expression “above” or “on” may indicate not only a case in which an element is directly above, below, left, and right and in contact with another element, but also a case in which the element is above, below, left, and right but is not in contact with the other element. As used herein, the singular terms “a” and “an” are intended to include the plural forms as well, unless the context clearly indicates otherwise. It will be further understood that when a part “includes” or “comprises” an element, unless otherwise defined, the part may further include other elements, not excluding the other elements.

The term “the” and other equivalent determiners may correspond to a singular referent or a plural referent. Unless orders of operations included in a method are specifically described or there are contrary descriptions, the operations may be performed according to appropriate orders.

Also, the terms such as “ . . . unit,” “module,” or the like used in the specification indicate an unit, which processes at least one function or motion, and the unit may be implemented by hardware or software, or by a combination of hardware and software.

The connecting lines, or connectors shown in the various figures presented are intended to represent exemplary functional relationships and/or physical or logical couplings between the various elements. It should be noted that many alternative or additional functional relationships, physical connections or logical connections may be present in a practical device.

The use of all examples or exemplary terms is to specifically describe the disclosure, and unless otherwise defined by the claims, the scope of the disclosure is not limited by these examples or exemplary terms.

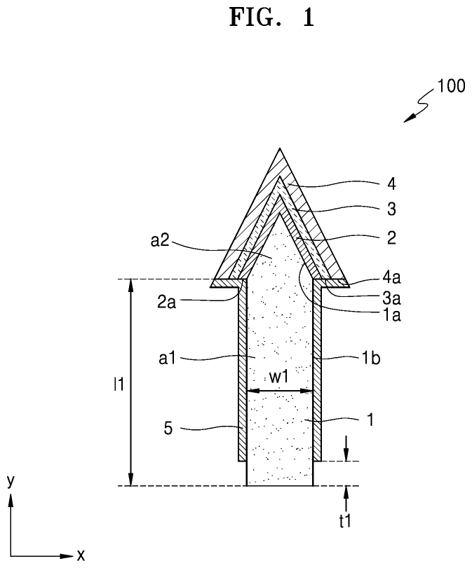

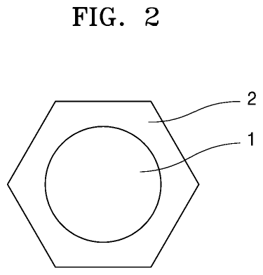

FIG. 1 is a schematic cross-sectional view illustrating a configuration of a nanorod light-emitting diode 100 according to an example embodiment. FIG. 2 is a plan view of a first conductivity-type semiconductor layer 1 and an active layer 2 included in the nanorod light-emitting diode 100 of FIG. 1.

Referring to FIG. 1, the nanorod light-emitting diode 100 according to an example embodiment may include the first conductivity-type semiconductor layer 1 including a body portion a1 having a nanorod shape, the active layer 2 covering an upper surface 1a of the first conductivity-type semiconductor layer 1, a second conductivity-type semiconductor layer 3 covering an upper surface of the active layer 2, an electrode layer 4 covering an upper surface of the second conductivity-type semiconductor layer 3, and an insulating layer 5 formed to surround a side surface 1b of the body portion a1 and expose a lower region of the side surface 1b of the body portion a1.

The first conductivity-type semiconductor layer 1 may have the body portion a1 and a top portion a2 formed on the body portion a1. The body portion a1 may have, for example, a cylindrical shape and the top portion a2 may be hexagonal pyramid shape a2. However, the disclosure is not limited thereto, and the body portion a1 may have a polygonal column shape, such as a rectangular parallelepiped.

The body portion a1 and the top portion a2 may include the same material as each other. According to an example embodiment, body portion a1 and the top portion a2 may be integrally provided as one body. The top portion a2 may be, for example, a truncated hexagonal pyramid shape.

A height l1 of the body portion a1 may be about 2 μm to about 7 μm. A diameter w1 of the body portion a1 may be about 50 nm to about 1000 nm. However, the disclosure is not limited thereto, and the height l1 of the body portion a1 may be less than about 2 μm or greater than about 7 μm and the diameter w1 of the body portion a1 may be less than about 50 nm. According to an example embodiment, the height of the top portion may be less than a height of the body portion.

The first conductivity-type semiconductor layer 1 may include an n-type semiconductor of Group III-V, for example, an n-type nitride semiconductor. The first conductivity-type semiconductor layer 1 may include, for example, Alₓ₁In_{y1}G_{a1-x1-y1}N (0≤x1≤1, 0≤y1≤1, and 0≤(x1+y1)≤1). The first conductivity-type semiconductor layer 1 may include InAlGaN, GaN, AlGaN, InGaN, AlN, InN, or a combination thereof. For example, the first conductivity-type semiconductor layer 1 may include n-GaN. The first conductivity-type semiconductor layer 1 may have a single-layer or multi-layer structure. The first conductivity-type semiconductor layer 1 may include a first conductivity-type dopant. The first conductivity-type semiconductor layer 1 may include an n-type dopant. For example, the first conductivity-type semiconductor layer 1 may include Si, Ge, Sn, or the like.

The active layer 2 may cover the upper surface 1a of the first conductivity-type semiconductor layer 1. For example, the active layer 2 may cover the upper surface 1a of the top portion a2 formed in an upper portion of the first conductivity-type semiconductor layer 1. In this case, the cross-section of the active layer 2 may have a V-shape corresponding to an upper region of the top portion a2. The active layer 2 may have a hexagonal cross-section in a top view of the nanorod light-emitting diode 100. Referring to FIG. 2, in a top view of the nanorod light-emitting diode 100, the cross-section of the first conductivity-type semiconductor layer 1 having a circular shape may be surrounded by the cross-section of the active layer 2 having a hexagonal shape. In addition, the active layer 2 may not cover the side surface 1b of the body portion a1. For example, the active layer 2 may be formed to cover the upper surface 1a of the first conductivity-type semiconductor layer 1 and not contact the side surface 1b of the body portion a1.

The upper surface of the top portion a2 may be a semi-polar surface. In this case, as the active layer 2 is provided on the semi-polar surface of the top portion a2, the amount of change in the wavelength of light emitted from the active layer 2 according to the amount of current may be reduced. Because the semi-polar surface has a relatively small piezoelectric field compared to a polar surface, it is possible to reduce the amount of change in wavelength according to the amount of current at a long wavelength. The long wavelength may refer to, for example, a wavelength of about 600 nm or more. The polar surface may represent a surface in a direction perpendicular to a stacking direction (i.e., a y direction) of the nanorod light-emitting diode 100, and the semi-polar surface may represent a surface having a slope of less than 90 degrees with respect to the stacking direction (i.e., the y direction) of the nanorod light-emitting diode 100. For example, the semi-polar surface may have a slope of approximately 45 degrees with respect to the stacking direction (i.e., the y-direction).

Light may be generated by a combination of electrons and holes in the active layer 2. The active layer 2 may have a multi-quantum well (MQW) structure or a single-quantum well (SQW) structure. The active layer 2 may include a semiconductor of Group III-V. The active layer 2 may include Alₓ₂In_{y2}G_{a1-x2-y2}N (0.1≤(x2+y2)≤1 and 0.1<y2<0.6), and may include, for example, GaN.

The second conductivity-type semiconductor layer 3 may cover the upper surface of the active layer 2. In this case, the second conductivity-type semiconductor layer 3 may have a V-shaped cross-section corresponding to the structure of the active layer 2 covering the top portion a2. In addition, the second conductivity-type semiconductor layer 3 may not extend to a region where the side surface 1b of the body portion a1 is provided. For example, the second conductivity-type semiconductor layer 3 may be formed to cover the upper surface of the active layer 2 and not face the region where the side surface 1b of the body portion a1 is provided. Accordingly, a lower surface 3a of the second conductivity-type semiconductor layer 3 may be formed parallel to a lower surface 2a of the active layer 2.

The second conductivity-type semiconductor layer 3 may include, for example, a p-type semiconductor. The second conductivity-type semiconductor layer 3 may include a p-type semiconductor of Group III-V. For example, the second conductivity-type semiconductor layer 3 may include Alₓ₁In_{y1}Ga_{1-x1-y1}N (0≤x1≤1, 0≤y1≤1, and 0≤(x1+y1)≤1). The second conductivity-type semiconductor layer 3 may include InAlGaN, GaN, AlGaN, InGaN, AlN, InN, or a combination thereof. For example, the second conductivity-type semiconductor layer 3 may include p-GaN. The second conductivity-type semiconductor layer 3 may have a single-layer or multi-layer structure. The second conductivity-type semiconductor layer 3 may include a second conductivity-type dopant. The second conductivity-type semiconductor layer 3 may include a p-type dopant. For example, the second conductivity-type semiconductor layer 3 may include Mg, B, or the like.

The electrode layer 4 may cover the upper surface of the second conductivity-type semiconductor layer 3. In this case, the electrode layer 4 may have a V-shaped cross-section corresponding to the structure of the active layer 2 covering the top portion a2. In addition, the electrode layer 4 may not extend to the region where the side surface 1b of the body portion a1 is provided. For example, the electrode layer 4 may be formed to cover the upper surface of the second conductivity-type semiconductor layer 3 and not face the region where the side surface 1b of the body portion a1 is provided. Accordingly, a lower surface 4a of the electrode layer 4 may be formed parallel to the lower surface 3a of the second conductivity-type semiconductor layer 3 and the lower surface 2a of the active layer 2.

The electrode layer 4 may include a conductive material. The electrode layer 4 may include a transparent conductive material. For example, the electrode layer 4 may include ITO, ZnO, or the like. Light generated from the active layer 2 may pass through the electrode layer 4 and be emitted to the outside. The electrode layer 4 may include Cr, Ti, Pt, Al, Au, Ni, an oxide or alloy thereof, or a mixture thereof, but is not limited thereto.

The insulating layer 5 may protect the first conductivity-type semiconductor layer 1 from an external environment, thereby increasing the reliability of the quality of the first conductivity-type semiconductor layer 1. The insulating layer 5 may include, for example, Al₂O₃, HfO₂, SiO₂, or SiN. The thickness of the insulating layer 5 may be several nm to several hundreds of nm.

The insulating layer 5 may be formed to surround the side surface 1b of the body portion a1. In this case, the insulating layer 5 may not entirely surround the side surface 1b of the body portion a1, and may surround only a part of the side surface 1b of the body portion a1. In other words, the insulating layer 5 may not surround the lower region of the side surface 1b of the body portion a1. Accordingly, the lower region of the side surface 1b of the body portion a1 may be exposed to the outside. In this case, the insulating layer 5 may directly contact the upper region of the side surface 1b of the body portion a1.

According to an example embodiment, the lower region of the side surface 1b of the body portion a1 that may be exposed to the outside may have a height t1. According to an example embodiment, the height t1 may be about 20 nm to about 100 nm. For example, the height t1 of the lower region of the side surface 1b of the body portion a1, the lower region being exposed to the outside, may be about 50 nm.

In addition, the insulating layer 5 may extend to cover the lower surface 2a of the active layer 2, the lower surface 3a of the second conductivity-type semiconductor layer 3, and the lower surface 4a of the electrode layer 4. The insulating layer 5 may be formed not to cover the upper surface 4a of the electrode layer 4. Accordingly, light emitted from the active layer 2 may be emitted to the outside through the electrode layer 4 that is transparent.

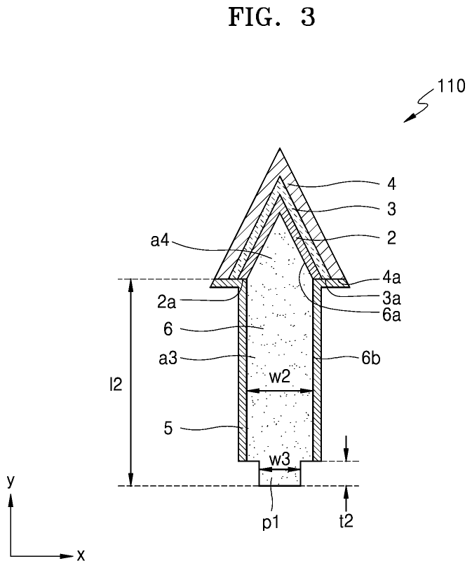

FIG. 3 is a schematic cross-sectional view illustrating a configuration of a nanorod light-emitting diode 110 according to another example embodiment.

The nanorod light-emitting diode 110 of FIG. 3 is substantially the same as the nanorod light-emitting diode 100 of FIG. 1 except that a protrusion p1 is formed in a lower portion of a body portion a3. Regarding FIG. 3, descriptions that are the same as those with respect to FIG. 1 may be omitted.

Referring to FIG. 3, the nanorod light-emitting diode 110 according to another example embodiment may include a first conductivity-type semiconductor layer 6 including the body portion a3 having a nanorod shape, an active layer 2 covering an upper surface 6a of the first conductivity-type semiconductor layer 6, a second conductivity-type semiconductor layer 3 covering an upper surface of the active layer 2, an electrode layer 4 covering an upper surface of the second conductivity-type semiconductor layer 3, and an insulating layer 5 formed to surround a side surface 6b of the body portion a3 and expose a lower region of the side surface 6b of the body portion a3.

The first conductivity-type semiconductor layer 6 may have the body portion a3 and a top portion a4 formed on the body portion a3. The body portion a3 may have, for example, a cylindrical shape and the top portion a4 may have a hexagonal pyramid shape. However, the disclosure is not limited thereto, and the body portion a3 may have a polygonal column shape, such as a rectangular parallelepiped.

The body portion a3 and the top portion a4 may include the same material and may be integrally provided as one body. The top portion a4 may be, for example, a truncated hexagonal pyramid shape.

The body portion a3 may be divided into an upper region having a relatively large diameter and a lower region having a relatively small diameter. For example, a first diameter w2 of the upper region of the body portion a3, of which the side surface is surrounded by the insulating layer 5, may be greater than a second diameter w3 of the lower region of the body portion a3, of which the side surface is exposed to the outside. In this case, the body portion a3 may include the protrusion p1 having the second diameter w3 that is relatively less than the first diameter w2 of a central portion of the body portion a3, that is, the first diameter w2 of the upper region of the body portion a3. The protrusion p1 may be formed to protrude from the center of the lower surface of the body portion a3. The protrusion p1 may be exposed to the outside by not being surrounded by the insulating layer 5, and a height t2 of the protrusion p1 may be about 20 nm to about 100 nm. For example, the height t2 of the protrusion p1 may be about 50 nm.

A height l2 of the body portion a3 may be about 2 μm to about 7 μm. The first diameter w2 of the body portion a3 may be about 50 nm to about 1000 nm. However, the disclosure is not limited thereto, and the height l2 of the body portion a3 may be less than about 2 μm or greater than about 7 μm and the first diameter w2 of the body portion a3 may be less than about 50 nm.

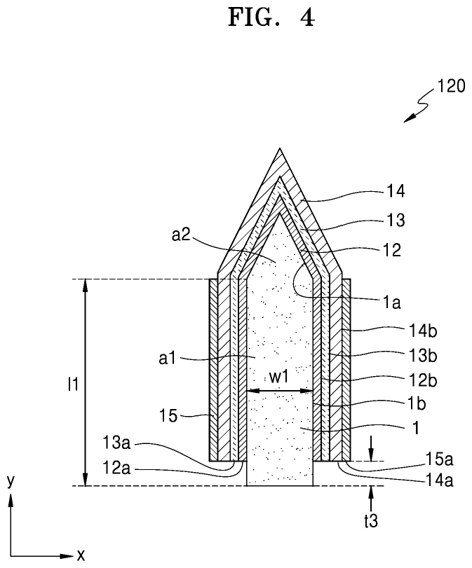

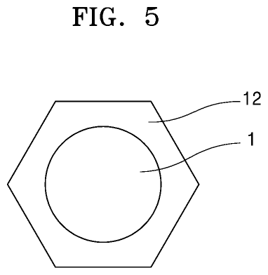

FIG. 4 is a schematic cross-sectional view illustrating a configuration of a nanorod light-emitting diode 120 according to another example embodiment. FIG. 5 is a plan view of a first conductivity-type semiconductor layer 1 and an active layer 12 included in the nanorod light-emitting diode 120 of FIG. 4.

The nanorod light-emitting diode 120 of FIG. 4 is substantially the same as the nanorod light-emitting diode 100 of FIG. 1 except that the active layer 12, a second conductivity-type semiconductor layer 13, and an electrode layer 14 extend to surround a side surface 1b of a body portion a1 and an insulating layer 15 is in contact with a side surface 14b of the electrode layer 14. Regarding FIG. 4, descriptions that are the same as those with respect to FIG. 1 may be omitted.

Referring to FIG. 4, the nanorod light-emitting diode 120 according to another example embodiment may include the first conductivity-type semiconductor layer 1 including the body portion a1 having a nanorod shape, the active layer 12 covering an upper surface 1a of the first conductivity-type semiconductor layer 1, the second conductivity-type semiconductor layer 13 covering an upper surface of the active layer 12, the electrode layer 14 covering an upper surface of the second conductivity-type semiconductor layer 13, and the insulating layer 15 formed to surround a side surface 1b of the body portion a1 and expose a lower region of the side surface 1b of the body portion a1.

The active layer 12 may cover the upper surface 1a of the first conductivity-type semiconductor layer 1. For example, the active layer 12 may cover the upper surface 1a of a top portion a2 formed in an upper portion of the first conductivity-type semiconductor layer 1. In this case, the cross-section of an upper portion of the active layer 12 may have a V-shape corresponding to an upper region of the top portion a2. The active layer 12 may have a hexagonal cross-section in a top view of the nanorod light-emitting diode 120. Referring to FIG. 5, in a top view of the nanorod light-emitting diode 120, the cross-section of the first conductivity-type semiconductor layer 1 having a circular shape may be surrounded by the cross-section of the active layer 12 having a hexagonal shape. In addition, the active layer 12 may extend to the side surface 1b of the body portion a1 to cover the side surface 1b of the body portion a1. For example, the active layer 12 may be formed to contact the upper surface 1a of the first conductivity-type semiconductor layer 1 and the side surface 1b of the body portion a1. Accordingly, the active layer 12 may surround the side surface 1b of the body portion a1.

In this case, the active layer 12 may not entirely cover the side surface 1b of the body portion a1, and may cover only a part of the side surface 1b of the body portion a1. In other words, the active layer 12 may not cover the lower region of the side surface 1b of the body portion a1. Accordingly, the lower region of the side surface 1b of the body portion a1 may be exposed to the outside, and the active layer 12 may directly contact an upper region of the side surface 1b of the body portion a1.

The second conductivity-type semiconductor layer 13 may cover the upper surface of the active layer 12. In this case, the cross-section of an upper portion of the second conductivity-type semiconductor layer 13 may have a V-shape corresponding to the structure of the active layer 12 covering the top portion a2. In addition, the second conductivity-type semiconductor layer 13 may extend to a side surface 12b of the active layer 12 covering the side surface 1b of the body portion a1. For example, the second conductivity-type semiconductor layer 13 may be formed to contact the upper surface of the active layer 12 and the side surface 12b of the active layer 12. Accordingly, the second conductivity-type semiconductor layer 13 may surround the side surface 1b of the body portion a1.

The second conductivity-type semiconductor layer 13 may be formed such that a lower surface 13a of the second conductivity-type semiconductor layer 13 is parallel to a lower surface 12a of the active layer 12. In this case, the second conductivity-type semiconductor layer 13 may be formed not to cover the lower region of the side surface 1b of the body portion a1 exposed to the outside because the lower region of the side surface 1b of the body portion a1 is not covered by the active layer 12.

The electrode layer 14 may cover an upper surface of the second conductivity-type semiconductor layer 13. In this case, the cross-section of an upper portion of the electrode layer 14 may have a V-shape corresponding to the structure of the active layer 12 covering the top portion a2. In addition, the electrode layer 14 may be formed to extend to a side surface 13b of the second conductivity-type semiconductor layer 13 covering the side surface 12b of the active layer 12. For example, the electrode layer 14 may be formed to contact the upper surface of the second conductivity-type semiconductor layer 13 and the side surface 13b of the second conductivity-type semiconductor layer 13. Accordingly, the electrode layer 14 may surround the side surface 1b of the body portion a1.

The electrode layer 14 may be formed such that a lower surface 14a of the electrode layer 14 is parallel to the lower surface 13a of the second conductivity-type semiconductor layer 13 and the lower surface 12a of the active layer 12. In this case, the electrode layer 14 may be formed not to cover the lower region of the side surface 1b of the body portion a1 exposed to the outside because the lower region of the side surface 1b is not covered by the active layer 12.

The insulating layer 15 may be formed to surround the side surface 14b of the electrode layer 14. The insulating layer 15 may be formed to directly contact the side surface 14b of the electrode layer 14. The insulating layer 15 may be formed such that a lower surface 15a of the insulating layer 15 is parallel to the lower surface 14a of the electrode layer 14, the lower surface 13a of the second conductivity-type semiconductor layer 13, and the lower surface 12a of the active layer 12. In this case, the insulating layer 15 may be formed not to cover the lower region of the side surface 1b of the body portion a1 exposed to the outside because the lower region of the side surface 1b is not covered by the active layer 12.

In addition, the insulating layer 15 may be formed not to cover the upper surface of the electrode layer 14. For example, the insulating layer 15 may be formed to cover only the side surface 14b of the electrode layer 14, and may not extend to the upper surface of the electrode layer 14.

A height t3 of the lower region of the side surface 1b of the body portion a1, the lower region being exposed to the outside by not being covered by the active layer 12, the second conductivity-type semiconductor layer 13, the electrode layer 14, and the insulating layer 15, may be about 20 nm to about 100 nm. For example, the height t3 of the lower region of the side surface 1b of the body portion a1, the lower region being exposed to the outside, may be about 50 nm.

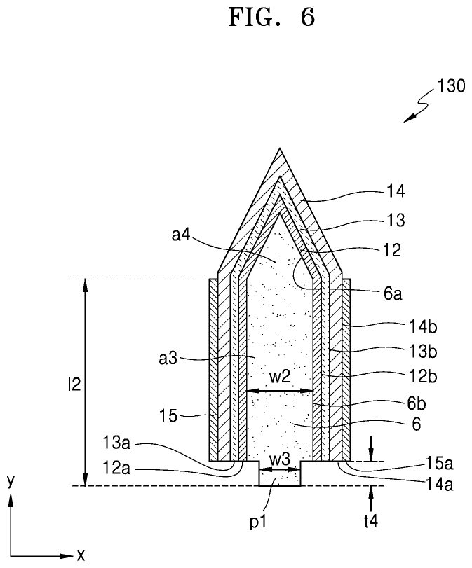

FIG. 6 is a schematic cross-sectional view illustrating a configuration of a nanorod light-emitting diode 130 according to another example embodiment.

The nanorod light-emitting diode 130 of FIG. 6 is substantially the same as the nanorod light-emitting diode 120 of FIG. 4 except that a protrusion p1 is formed in a lower portion of a body portion a3. Regarding FIG. 6, descriptions that are the same as those with respect to FIGS. 1 and 4 may be omitted.

Referring to FIG. 6, the nanorod light-emitting diode 130 according to another example embodiment may include a first conductivity-type semiconductor layer 6 including the body portion a3 having a nanorod shape, an active layer 12 covering an upper surface 6a of the first conductivity-type semiconductor layer 6, a second conductivity-type semiconductor layer 13 covering an upper surface of the active layer 12, an electrode layer 14 covering an upper surface of the second conductivity-type semiconductor layer 13, and an insulating layer 15 formed to surround a side surface 6b of the body portion a3 and expose a lower region of the side surface 6b of the body portion a3.

The first conductivity-type semiconductor layer 6 may have the body portion a3 and a top portion a4 formed on the body portion a3. The body portion a3 may have, for example, a cylindrical shape. However, the disclosure is not limited thereto, and the body portion a3 may have a polygonal column shape, such as a rectangular parallelepiped.

The body portion a3 and the top portion a4 may include the same material and may be integrally provided as one body. The top portion a4 may be, for example, a truncated hexagonal pyramid shape.

The body portion a3 may be divided into an upper region having a relatively large diameter and a lower region having a relatively small diameter. For example, a first diameter w2 of the upper region of the body portion a3, of which the side surface is surrounded by the insulating layer 15, may be greater than a second diameter w3 of the lower region of the body portion a3, of which the side surface is exposed to the outside. In this case, the body portion a3 may include the protrusion p1 having the second diameter w3 that is relatively less than the first diameter w2 of a central portion of the body portion a3, that is, the first diameter w2 of the upper region of the body portion a3. The protrusion p1 may be formed to protrude from the center of the lower surface of the body portion a3. The protrusion p1 may be exposed to the outside by not being surrounded by the active layer 12, the second conductivity-type semiconductor layer 13, the electrode layer 14, and the insulating layer 15, and a height t4 of the protrusion p1 may be about 20 nm to about 100 nm. For example, the height t4 of the protrusion p1 may be about 50 nm.

A height l2 of the body portion a3 may be about 2 μm to about 7 μm. The first diameter w2 of the body portion a3 may be about 50 nm to about 1000 nm. However, the disclosure is not limited thereto, and the height l2 of the body portion a3 may be less than about 2 μm or greater than about 7 μm and the first diameter w2 of the body portion a3 may be less than about 50 nm.

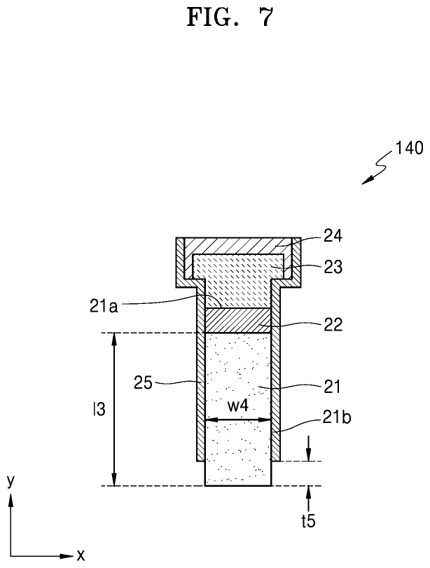

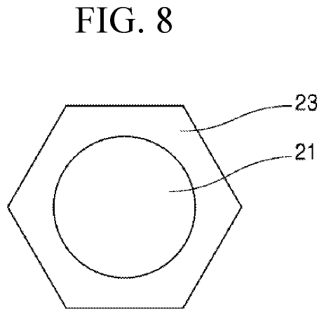

FIG. 7 is a schematic cross-sectional view illustrating a configuration of a nanorod light-emitting diode 140 according to another example embodiment. FIG. 8 is a plan view of a first conductivity-type semiconductor layer 21 and a second conductivity-type semiconductor layer 23 included in the nanorod light-emitting diode 140 of FIG. 7.

Referring to FIG. 7, the nanorod light-emitting diode 140 according to another example embodiment may include the first conductivity-type semiconductor layer 21 having a nanorod shape, an active layer 22 covering an upper surface 21a of the first conductivity-type semiconductor layer 21, the second conductivity-type semiconductor layer 23 covering an upper surface of the active layer 22, an electrode layer 24 covering an upper surface of the second conductivity-type semiconductor layer 23, and an insulating layer 25 formed to surround a side surface 21b of the first conductivity-type semiconductor layer 21 and expose a lower region of the side surface 21b of the first conductivity-type semiconductor layer 21.

The first conductivity-type semiconductor layer 21 may have a structure having the same diameter as a whole. The first conductivity-type semiconductor layer 21 may have, for example, a cylindrical shape. However, the disclosure is not limited thereto, and the first conductivity-type semiconductor layer 21 may have a polygonal column shape, such as a rectangular parallelepiped.

A height l3 of the first conductivity-type semiconductor layer 21 may be about 2 μm to about 7 μm. A diameter w4 of the first conductivity-type semiconductor layer 21 may be about 50 nm to about 1000 nm. However, the disclosure is not limited thereto, and the height l3 of the first conductivity-type semiconductor layer 21 may be less than about 2 μm or greater than about 7 μm and the diameter w4 of the first conductivity-type semiconductor layer 21 may be less than about 50 nm.

The first conductivity-type semiconductor layer 21 may include an n-type semiconductor of Group III-V, for example, an n-type nitride semiconductor. A material that may be included in the first conductivity-type semiconductor layer 21 is the same as a material that may be included in the first conductivity-type semiconductor layer 1 of FIG. 1, and thus, a description thereof is omitted herein.

The active layer 22 may cover the upper surface 21a of the first conductivity-type semiconductor layer 21. For example, the active layer 22 may cover the upper surface 21a, which is flat, of the first conductivity-type semiconductor layer 21. In this case, a lower surface of the active layer 22 may be flat. Also, an upper surface of the active layer 22 may be formed to be flat like the lower surface of the active layer 22.

The active layer 22 may have a hexagonal column shape. In this case, the active layer 22 may have a hexagonal cross-section in a top view of the nanorod light-emitting diode 140.

Light may be generated by a combination of electrons and holes in the active layer 22. The active layer 22 may have an MQW structure or an SQW structure. A material that may be included in the active layer 22 is the same as a material that may be included in the active layer 2 of FIG. 1, and thus, a description thereof is omitted herein.

The second conductivity-type semiconductor layer 23 may cover the upper surface of the active layer 22. For example, the second conductivity-type semiconductor layer 23 may cover a flat upper surface of the active layer 22. In this case, a lower surface of the second conductivity-type semiconductor layer 23 may be flat. The second conductivity-type semiconductor layer 23 may have a hexagonal column shape. In this case, the second conductivity-type semiconductor layer 23 may have a hexagonal cross-section in a top view of the nanorod light-emitting diode 140. The second conductivity-type semiconductor layer 23 may have a T-shape. Accordingly, the diameter of the lower surface of the second conductivity-type semiconductor layer 23, which is in contact with the upper surface of the active layer 22, may be less than the diameter of the upper surface of the second conductivity-type semiconductor layer 23. Referring to FIG. 8, in a top view of the nanorod light-emitting diode 140, the cross-section of the first conductivity-type semiconductor layer 21 in a circular shape may be surrounded by the cross-section of an upper region of the second conductivity-type semiconductor layer 23 in a hexagonal shape.

The second conductivity-type semiconductor layer 23 may include, for example, a p-type semiconductor. A material that may be included in the second conductivity-type semiconductor layer 23 is the same as a material that may be included in the second conductivity-type semiconductor layer 3 of FIG. 1, and thus, a description thereof is omitted herein.

The electrode layer 24 may cover the upper surface of the second conductivity-type semiconductor layer 23. In addition, the electrode layer 24 may cover a side surface of the upper region of the second conductivity-type semiconductor layer 23 having a T-shape. Accordingly, the upper surface and side surface of the upper region of second conductivity-type semiconductor layer 23 having a relatively larger diameter than that of a lower region of the second conductivity-type semiconductor layer 23 may be covered by the electrode layer 24.

The electrode layer 24 may include a conductive material. A material that may be included in the electrode layer 24 is the same as a material that may be included in the electrode layer 24 of FIG. 1, and thus, a description thereof is omitted herein.

The insulating layer 25 may protect the first conductivity-type semiconductor layer 21 from an external environment, thereby increasing the reliability of the quality of the first conductivity-type semiconductor layer 21. The insulating layer 25 may include, for example, Al₂O₃, HfO₂, SiO₂, or SiN. The thickness of the insulating layer 25 may be several nm to several hundreds of nm.

The insulating layer 25 may be formed to surround a side surface of the first conductivity-type semiconductor layer 21, a side surface of the active layer 22, a side surface of the second conductivity-type semiconductor layer 23, and a side surface of the electrode layer 24. In this case, the insulating layer 25 may not entirely surround the side surface 21b of the first conductivity-type semiconductor layer 21, but may surround only a part of the side surface 21b of the first conductivity-type semiconductor layer 21. In other words, the insulating layer 25 may not surround a lower region of the side surface 21b of the first conductivity-type semiconductor layer 21. Accordingly, the lower region of the side surface 21b of the first conductivity-type semiconductor layer 21 may be exposed to the outside. In this case, the insulating layer 25 may be formed to directly contact an upper region of the side surface 21b of the first conductivity-type semiconductor layer 21, the side surface of the active layer 22, the side surface of the second conductivity-type semiconductor layer 23, and the side surface of the electrode layer 24.

The side surface of the first conductivity-type semiconductor layer 21, the side surface of the active layer 22, and the side surface of a lower region of the second conductivity-type semiconductor layer 23 having a T-shape may be parallel to one another to constitute a single plane. A stepped portion may be formed between an upper region and a lower region of the second conductivity-type semiconductor layer 23 having a T-shape, and the insulating layer 25 may cover a surface of the stepped portion. As shown in FIG. 5, the insulating layer 25 may be continuously formed to cover an upper region of the side surface of the first conductivity-type semiconductor layer 21, the side surface of the active layer 22, the side surface of the lower region of the second conductivity-type semiconductor layer 23 having a T-shape, the side surface of the electrode layer 24, and the surface of the stepped portion formed between the upper region and the lower region of the second conductivity-type semiconductor layer 23 having a T-shape.

A height t5 of the lower region of the side surface 21b of the first conductivity-type semiconductor layer 21, the lower region being exposed to the outside by not being covered by the insulating layer 25, may be about 20 nm to about 100 nm. For example, the height t5 of the lower region of the side surface 21b of the first conductivity-type semiconductor layer 21, the lower region being exposed to the outside, may be about 50 nm.

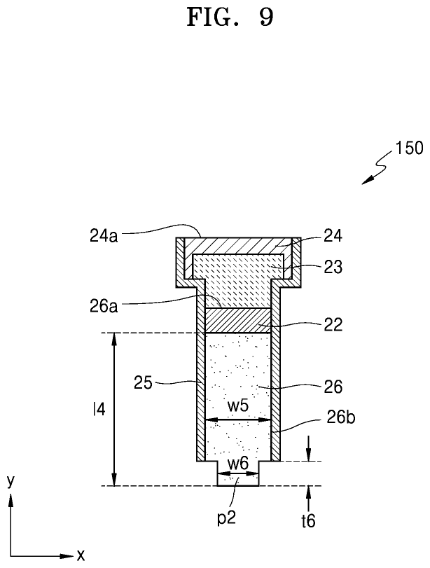

FIG. 9 is a schematic cross-sectional view illustrating a configuration of a nanorod light-emitting diode 150 according to another example embodiment.

The nanorod light-emitting diode 150 of FIG. 9 is substantially the same as the nanorod light-emitting diode 140 of FIG. 7 except that a protrusion p2 is formed in a lower portion of a first conductivity-type semiconductor layer 1. Regarding FIG. 9, descriptions that are the same as those with respect to FIG. 7 may be omitted.

Referring to FIG. 9, the nanorod light-emitting diode 140 according to another example embodiment may include a first conductivity-type semiconductor layer 26 having a nanorod shape, an active layer 22 covering an upper surface 26a of the first conductivity-type semiconductor layer 26, a second conductivity-type semiconductor layer 23 covering an upper surface of the active layer 22, an electrode layer 24 covering an upper surface of the second conductivity-type semiconductor layer 23, and an insulating layer 25 formed to surround a side surface 26b of the first conductivity-type semiconductor layer 26 and expose a lower region of the side surface 26b of the first conductivity-type semiconductor layer 26.

The first conductivity-type semiconductor layer 26 may have a structure having the same diameter as a whole. The first conductivity-type semiconductor layer 26 may have, for example, a cylindrical shape. However, the disclosure is not limited thereto, and the first conductivity-type semiconductor layer 26 may have a polygonal column shape, such as a rectangular parallelepiped.

The first conductivity-type semiconductor layer 26 may be divided into an upper region having a relatively large diameter and a lower region having a relatively small diameter. For example, a first diameter w5 of the upper region of the first conductivity-type semiconductor layer 26, of which the side surface is surrounded by the insulating layer 25, may be greater than a second diameter w6 of the lower region of the first conductivity-type semiconductor layer 26, of which the side surface is exposed to the outside. In this case, the first conductivity-type semiconductor layer 26 may include the protrusion p2 having the second diameter w6 that is relatively less than the first diameter w5 of a central portion of the first conductivity-type semiconductor layer 26, that is, the first diameter w5 of the upper region of the first conductivity-type semiconductor layer 26. The protrusion p2 may be formed to protrude from the center of the lower surface of the first conductivity-type semiconductor layer 26. The protrusion p2 may be exposed to the outside by not being surrounded by the insulating layer 25, and a height t6 of the protrusion p2 may be about 20 nm to about 100 nm. For example, the height t6 of the protrusion p2 may be about 50 nm.

A height l4 of the first conductivity-type semiconductor layer 26 may be about 2 μm to about 7 μm. In addition, the first diameter w5 of the first conductivity-type semiconductor layer 26 may be about 50 nm to about 1000 nm. However, the disclosure is not limited thereto, and the height l4 of the first conductivity-type semiconductor layer 26 may be less than about 2 μm or greater than about 7 μm and the first diameter w5 of the first conductivity-type semiconductor layer 26 may be less than about 50 nm.

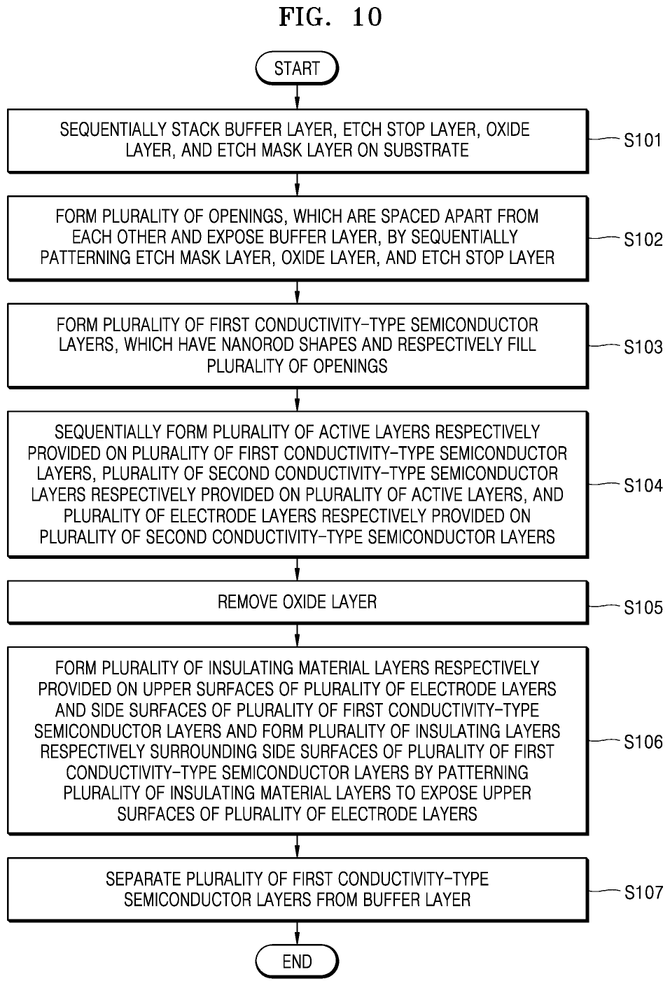

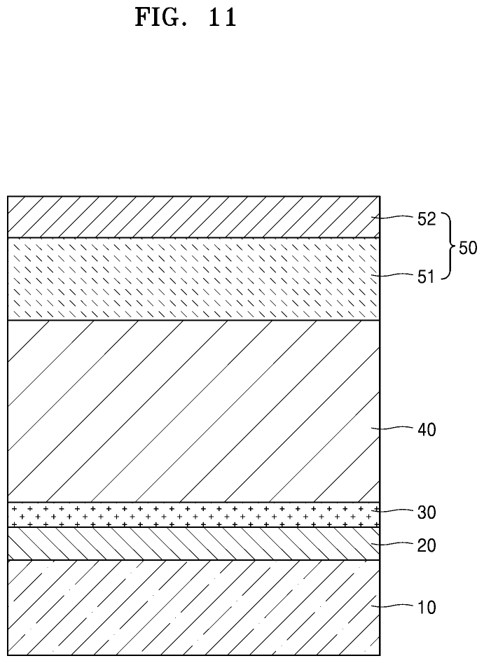

FIG. 10 is a flowchart illustrating a method of manufacturing a nanorod light-emitting diode, according to an example embodiment. FIGS. 11 to 20 are views for explaining the method of manufacturing a nanorod light-emitting diode, which is illustrated in FIG. 10.

Referring to FIG. 10, the method of manufacturing a nanorod light-emitting diode, according to an example embodiment, is described. The method may include: operation S101 of sequentially stacking a buffer layer 20, an etch stop layer 30, an oxide layer 40, and an etch mask layer 50 on a substrate 10; operation S102 of forming a plurality of openings h3 and h4, which are spaced apart from each other and expose the buffer layer 20, by sequentially patterning the etch mask layer 50, the oxide layer 40, and the etch stop layer 30; operation S103 of forming a first conductivity-type semiconductor material layer 70 filling the plurality of openings h3 and h4 and covering an upper surface of the oxide layer 40 and forming a plurality of first conductivity-type semiconductor layers 71 and 72, which have nanorod shapes and respectively fill the plurality of openings h3 and h4, by patterning the first conductivity-type semiconductor material layer 70; operation S104 of sequentially forming a plurality of active layers 73 and 74 respectively provided on the plurality of first conductivity-type semiconductor layers 71 and 72, a plurality of second conductivity-type semiconductor layers 75 and 76 respectively provided on the plurality of active layers 73 and 74, and a plurality of electrode layers 77 and 78 respectively provided on the plurality of second conductivity-type semiconductor layers 75 and 76; and operation S105 of removing the oxide layer 40. The method of manufacturing a nanorod light-emitting diode may further include: operation S106 of forming a plurality of insulating material layers 80 and 81 respectively provided on upper surfaces 77a and 78a of the plurality of electrode layers 77 and 78 and side surfaces 71b and 72b of the plurality of first conductivity-type semiconductor layers 71 and 72 and forming a plurality of insulating layers 82 and 83 respectively surrounding the side surfaces 71b and 72b of the plurality of first conductivity-type semiconductor layers 71 and 72 by patterning the plurality of insulating material layers 80 and 81 to expose the upper surfaces 77a and 78a of the plurality of electrode layers 77 and 78; and operation S107 of separating the plurality of first conductivity-type semiconductor layers 71 and 72 from the buffer layer 20.

Referring to FIG. 11, in operation S101 of sequentially stacking the buffer layer 20, the etch stop layer 30, the oxide layer 40, and the etch mask layer 50 on the substrate 10, first, the buffer layer 20 may be formed on the substrate 10 by a method, such as metal-organic chemical vapor deposition (MOCVD), plasma enhanced chemical vapor deposition (PECVD), low pressure chemical vapor deposition (LPCVD), pulsed laser deposition (PLD), hydride vapor phase epitaxy (HVPE), or molecular beam epitaxy (MBE). In addition, the buffer layer 20 may be formed on the substrate 10 by physical vapor deposition (PVD), such as E-beam evaporation and sputtering, or atomic layer deposition (ALD).

The substrate 10 may include a crystalline substrate. For example, the substrate 10 may include any one of Si, SiC, GaN, GaAs, GaP, sapphire, graphene, and transition metal dichalcogenide (TMD). The substrate 10 may have a crystal orientation of (001), (110), (111), or the like. However, the disclosure is not limited thereto, and the substrate 10 may include an amorphous substrate, such as glass or plastic.

The buffer layer 20 may include aluminum nitride. For example, the buffer layer 20 may include AlN. The buffer layer 20 may have a crystal orientation in a (002) direction. The thickness of the buffer layer 20 may be about 5 nm to about 200 nm.

For example, in the case of using PLD, the buffer layer 20 including AlN having a crystal orientation in the (002) direction may be formed on the substrate 10 including Si, provided in a process chamber, by using an AlN target material and a pulse laser in the process chamber in N₂ atmosphere. In this case, post annealing may be performed such that the buffer layer 20 has a crystal orientation in the (002) direction.

For example, the buffer layer 20 including AlN may be epitaxially formed, by using the MOCVD and MBE, on the substrate 10 including Si having a crystal orientation in a (111) direction under a process temperature of about 700° C. to about 1200° C. In this case, examples of usable precursors include trimethyl aluminum (TMAl), triethyl aluminum (TEAl), trimethylamine alane (TMAAl), and ammonia (NH₃).

For example, in the case of using sputtering, the buffer layer 20 including AlN having a crystal orientation in the (002) direction may be formed on the substrate 10 including Si, provided in a process chamber, by using an AlN target material in the process chamber at high temperature and N₂ atmosphere. In this case, the process temperature may be about 200° C. to about 1000° C. In addition, post annealing may be performed such that the buffer layer 20 has a crystal orientation in the (002) direction.

After the buffer layer 20 is formed on the substrate 10, the etch stop layer 30, the oxide layer 40, and the etch mask layer 50 are formed using the various deposition methods listed above.

The etch stop layer 30 may include any one of amorphous silicon and silicon oxide. The etch stop layer 30 may provide a sufficiently large etch selectivity with respect to the oxide layer 40 deposited thereon. The thickness of the etch stop layer 30 may be about 20 nm to about 100 nm. For example, the etch stop layer 30 may be formed on the buffer layer 20 by using a method, such as sputtering or LPCVD.

The oxide layer 40 may include an insulating material. For example, the oxide layer 40 may include SiO₂, SiN, Al₂O₃, or the like. The thickness of the oxide layer 40 may be about 2 μm to about 6 μm.

The etch mask layer 50 may have a double-layer structure in which a first layer 51 and a second layer 52 are sequentially stacked. For example, the first layer 51 may include an amorphous carbon layer (ACL), and the second layer 52 may include SiON. However, the disclosure is not limited thereto, and the etch mask layer 50 may be a single layer. Also, the etch mask layer 50 may include other types of materials other than those listed above.

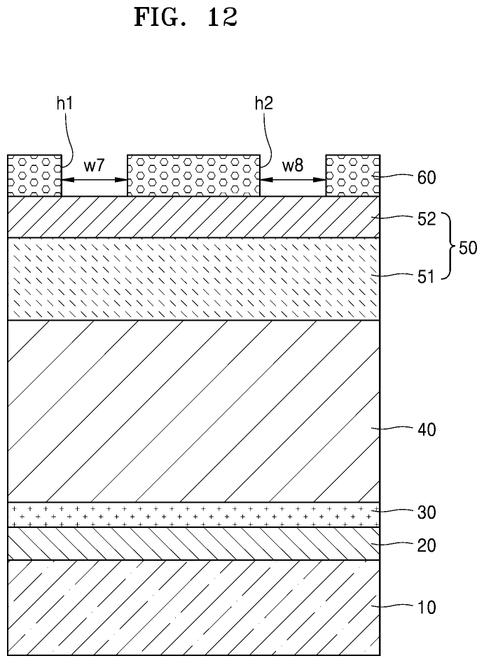

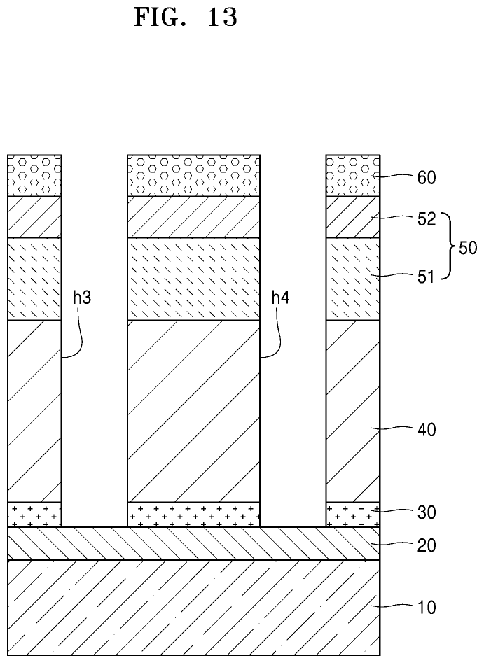

Referring to FIGS. 12 and 13, in operation S102 of forming the plurality of openings h3 and h4, which are apart from each other and expose the buffer layer 20, by sequentially patterning the etch mask layer 50, the oxide layer 40, and the etch stop layer 30, the etch mask layer 50, the oxide layer 40, and the etch stop layer 30 may be sequentially patterned using a photolithography process.

First, a photoresist 60 is formed on the etch mask layer 50, and a plurality of openings, e.g., a first opening h1 and a second opening h2, are formed in the photoresist 60 through an exposure process. Although two openings, i.e., the first opening h1 and the second opening h2, are illustrated in FIG. 12, this case is merely an example and a large number of holes may be formed in the photoresist 60. In this case, the first opening h1 and the second opening h2 may be formed in the photoresist 60. The second layer 52 may be exposed to the outside through the first and second openings h1 and h2. A first diameter w7 of the first opening h1 and a second diameter w8 of the second opening h2 may each be about 50 nm to about 1000 nm. However, the disclosure is not limited thereto, and each of the first diameter w7 of the first opening h1 and the second diameter w8 of the second opening h2 may be less than about 50 nm.

The etch mask layer 50 exposed by the first and second openings h1 and h2 of the photoresist 60 is etched. After the etch mask layer 50 is etched, the oxide layer 40 and the etch stop layer 30 are sequentially etched through a dry etching process. The etch mask layer 50, the oxide layer 40, and the etch stop layer 30 may be etched through a dry etching process. In this case, an ICP-RIE apparatus may be used for the etching process. After the etch mask layer 50, the oxide layer 40, and the etch stop layer 30 are etched, the plurality of openings h3 and h4 passing through the etch mask layer 50, the oxide layer 40, and the etch stop layer 30 and exposing the buffer layer 20 to the outside may be formed. The plurality of openings h3 and h4 may include a third opening h3 connected to the first opening h1 and a fourth opening h4 connected to the second opening h2.

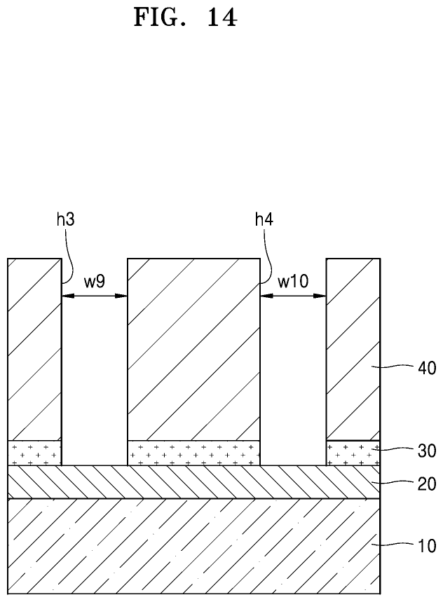

Referring to FIG. 14, after the etch mask layer 50, the oxide layer 40, and the etch stop layer 30 are etched, a remaining portion of the etch mask layer 50 may be removed. For example, a portion of the etch mask layer 50 remaining on the oxide layer 40 may be removed through an ashing process and a wet process. A third diameter w9 of the third opening h3 and a fourth diameter w10 of the fourth opening h4 may each be about 50 nm to about 1000 nm. However, the disclosure is not limited thereto, and each of the third diameter w9 of the third opening h3 and the fourth diameter w10 of the fourth opening h4 may be less than about 50 nm.

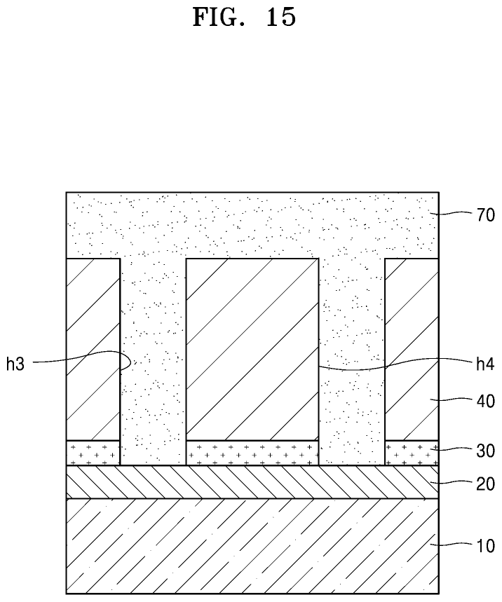

Referring to FIG. 15, in operation S103 of forming the plurality of first conductivity-type semiconductor layers 71 and 72, the first conductivity-type semiconductor material layer 70 filling the plurality of openings h3 and h4 and covering the upper surface of the oxide layer 40 may be formed. The first conductivity-type semiconductor material layer 70 may include an n-type semiconductor of Group III-V, for example, an n-type nitride semiconductor. The first conductivity-type semiconductor material layer 70 may include, for example, Alₓ₁In_{y1}G_{a1-x1-y1}N (0≤x1≤1, 0≤y1≤1, and 0≤(x1+y1)≤1). The first conductivity-type semiconductor material layer 70 may include InAlGaN, GaN, AlGaN, InGaN, AlN, InN, or a combination thereof. For example, the first conductivity-type semiconductor material layer 70 may include n-GaN. The first conductivity-type semiconductor material layer 70 may have a single-layer or multi-layer structure.

The first conductivity-type semiconductor material layer 70 may be formed by an epitaxial growth method, such as MOCVD, MBE, or HPVE. However, the disclosure is not limited thereto, and the first conductivity-type semiconductor material layer 70 may be formed by various methods other than the methods listed above.

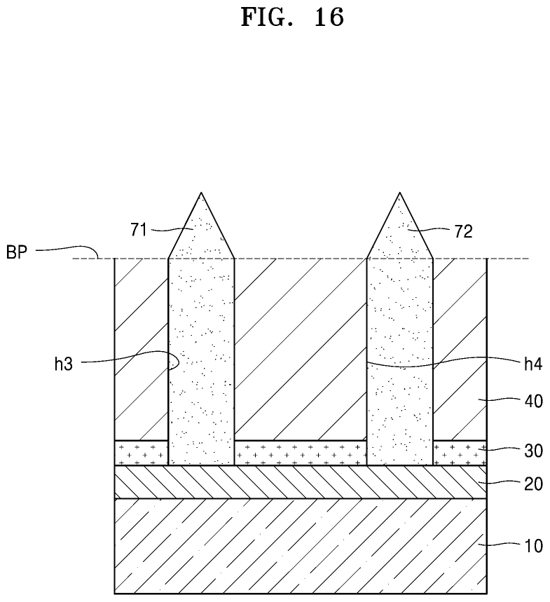

Referring to FIG. 16, the plurality of first conductivity-type semiconductor layers 71 and 72, which have nanorod shapes and respectively fill the plurality of openings h3 and h4, may be formed by patterning the first conductivity-type semiconductor material layer 70. In this case, the first conductivity-type semiconductor material layer 70 may be patterned such that upper surfaces of the plurality of first conductivity-type semiconductor layers 71 and 72 are higher than the upper surface of the oxide layer 40 with respect to a reference plane BP parallel to the upper surface of the oxide layer 40.

For example, the first conductivity-type semiconductor material layer 70 may be patterned such that an upper portion of each of the plurality of first conductivity-type semiconductor layers 71 and 72 has a hexagonal pyramid shape. The hexagonal pyramid shape of each of the plurality of first conductivity-type semiconductor layers 71 and 72 may be positioned higher than the upper surface of the oxide layer 40 with respect to the reference plane BP. Each of the plurality of first conductivity-type semiconductor layers 71 and 72 may have a hexagonal pyramid shape, for example, a truncated hexagonal pyramid shape.

Each of the plurality of first conductivity-type semiconductor layers 71 and 72 may include a first conductivity-type dopant. Each of the plurality of first conductivity-type semiconductor layers 71 and 72 may include an n-type dopant, for example, Si, Ge, Sn, or the like.

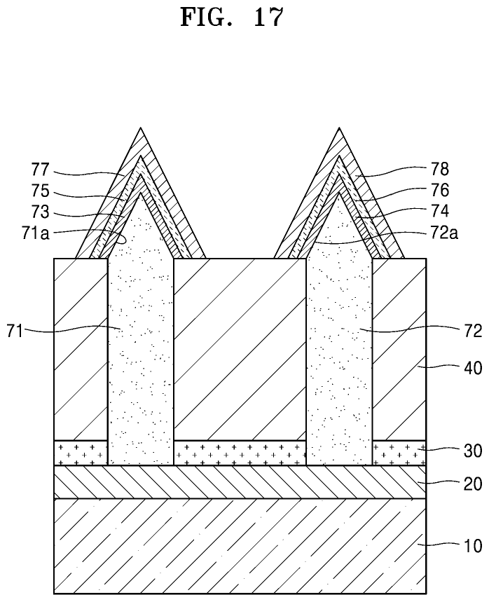

Referring to FIG. 17, in operation S104 of sequentially forming the plurality of active layers 73 and 74, the plurality of second conductivity-type semiconductor layers 75 and 76, and the plurality of electrode layers 77 and 78, a stacked structure may be formed on the plurality of first conductivity-type semiconductor layers 71 and 72 by using an epitaxial growth method, such MOCVD, MBE, or HPVE. However, the disclosure is not limited thereto, and the plurality of active layers 73 and 74, the plurality of second conductivity-type semiconductor layers 75 and 76, and the plurality of electrode layers 77 and 78 may be formed by various other methods other than those listed above.

First, the plurality of active layers 73 and 74 respectively covering upper surfaces 71a and 72a of the plurality of first conductivity-type semiconductor layers 71 and 72 may be formed. The plurality of active layers 73 and 74 may cover the upper surfaces 71a and 72a of the plurality of first conductivity-type semiconductor layers 71 and 72, respectively. For example, the plurality of active layers 73 and 74 may respectively cover the upper surfaces 71a and 72a of hexagonal pyramid shapes respectively formed in upper portions of the plurality of first conductivity-type semiconductor layers 71 and 72. In this case, the cross-sections of the plurality of active layers 73 and 74 may respectively have V-shapes corresponding to hexagonal pyramid-shaped upper regions of the plurality of first conductivity-type semiconductor layers 71 and 72.

Light may be generated while electrons and holes are combined in the plurality of active layers 73 and 74. Each of the plurality of active layers 73 and 74 may have an MQW structure or an SQW structure. Each of the plurality of active layers 73 and 74 may include a semiconductor of Group III-V. Each of the plurality of active layers 73 and 74 may include Alₓ₂In_{y2}Ga_{1-x2-y2}N (0.1≤(x2+y2)≤1 and 0.1<y2<0.6), and may include, for example, GaN.

The plurality of second conductivity-type semiconductor layers 75 and 76, which respectively cover upper surfaces of the plurality of active layers 73 and 74, may be formed. The plurality of second conductivity-type semiconductor layers 75 and 76 may cover upper surfaces of the plurality of active layers 73 and 74, respectively. In this case, the plurality of second conductivity-type semiconductor layers 75 and 76 may respectively have V-shaped cross-sections corresponding to the structures of the plurality of active layers 73 and 74 covering the hexagonal pyramid shapes formed in upper portions of the plurality of first conductivity-type semiconductor layers 71 and 72.

Each of the plurality of second conductivity-type semiconductor layers 75 and 76 may include, for example, a p-type semiconductor. Each of the plurality of second conductivity-type semiconductor layers 75 and 76 may include a p-type semiconductor of Group III-V. For example, each of the plurality of second conductivity-type semiconductor layers 75 and 76 may include Alₓ₁In_{y1}Ga_{1-x1-y1}N (0≤x1≤1, 0≤y1≤1, and 0≤(x1+y1)≤1). Each of the plurality of second conductivity-type semiconductor layers 75 and 76 may include InAlGaN, GaN, AlGaN, InGaN, AlN, InN, or a combination thereof. For example, each of the plurality of second conductivity-type semiconductor layers 75 and 76 may include p-GaN. Each of the plurality of second conductivity-type semiconductor layers 75 and 76 may have a single-layer or multi-layer structure. Each of the plurality of second conductivity-type semiconductor layers 75 and 76 may include a second conductivity-type dopant. Each of the plurality of second conductivity-type semiconductor layers 75 and 76 may include a p-type dopant, for example, Mg, B, or the like.

The plurality of electrode layers 77 and 78, which respectively cover upper surfaces of the plurality of second conductivity-type semiconductor layers 75 and 76, may be formed. The plurality of electrode layers 77 and 78 may cover the upper surfaces of the plurality of second conductivity-type semiconductor layers 75 and 76, respectively. In this case, the plurality of electrode layers 77 and 78 may respectively have V-shaped cross-sections corresponding to the structures of the plurality of active layers 73 and 74 covering the hexagonal pyramid shapes respectively formed in upper portions of the plurality of first conductivity-type semiconductor layers 71 and 72.

Each of the plurality of electrode layers 77 and 78 may include a conductive material. Each of the plurality of electrode layers 77 and 78 may include a transparent conductive material. For example, each of the plurality of electrode layers 77 and 78 may include ITO, ZnO, or the like. In addition, each of the plurality of electrode layers 77 and 78 may include Cr, Ti, Pt, Al, Au, Ni, an oxide or alloy thereof, or a mixture thereof, but is not limited thereto.

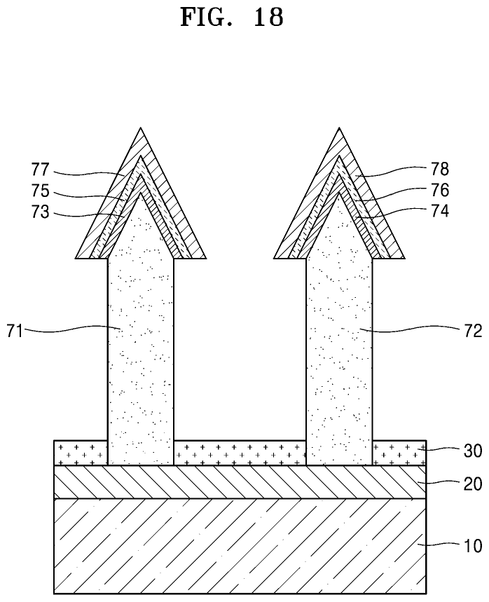

Referring to FIG. 18, in operation S105 of removing the oxide layer 40, the oxide layer 40 surrounding the side surfaces of the plurality of first conductivity-type semiconductor layers 71 and 72 may be removed. In this case, the oxide layer 40 may be removed through a wet process using a buffered oxide etchant (BOE) solution, an LAL solution (combination of NH₄F, HF and H₂O), hydrogen fluoride (HF), or the like.

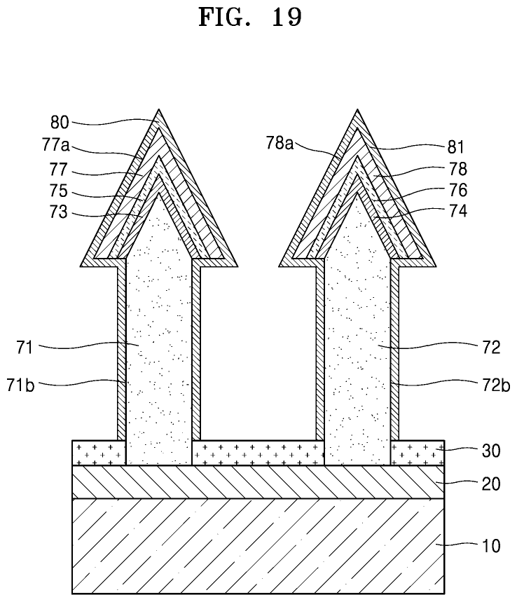

Referring to FIG. 19, in operation S106 of forming the plurality of insulating material layers 80 and 81, the plurality of insulating material layers 80 and 81, which are in contact with the upper surfaces 77a and 78a of the plurality of electrode layers 77 and 78 and the side surfaces 71b and 72b of the plurality of first conductivity-type semiconductor layers 71 and 72, may be formed. The plurality of insulating material layers 80 and 81 may be formed to respectively cover the outer surfaces of structures in which the plurality of first conductivity-type semiconductor layers 71 and 72, the plurality of active layers 73 and 74, the plurality of second conductivity-type semiconductor layers 75 and 76, and the plurality of electrode layers 77 and 78 are stacked.

The plurality of insulating material layers 80 and 81 may be formed by an ALD method, but is not limited thereto and may also be formed by a PECVD method. The plurality of insulating material layers 80 and 81 may include, for example, Al₂O₃, HfO₂, SiO₂, or SiN. The thicknesses of the plurality of insulating material layers 80 and 81 may be several nm to several hundreds of nm.

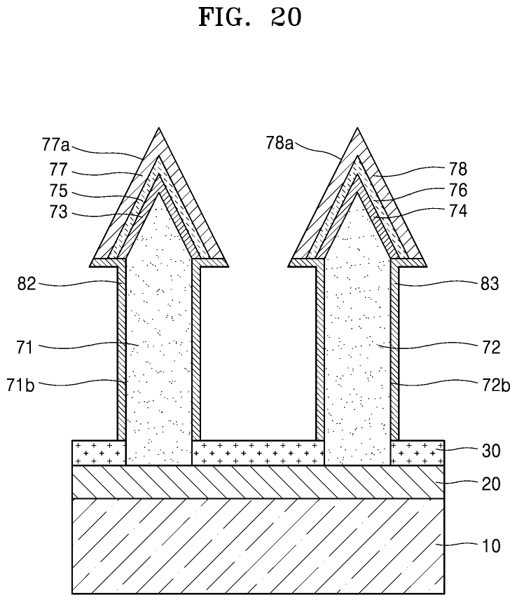

Referring to FIG. 20, the plurality of insulating material layers 80 and 81 may be patterned to expose the upper surfaces 77a and 78a of the plurality of electrode layers 77 and 78, respectively. In this case, the plurality of insulating material layers 80 and 81 may be patterned using an anisotropic etch back method. In this process, a hydrophobic film may be further formed on the plurality of insulating material layers 80 and 81. The hydrophobic film may make semiconductor structures surrounded by the plurality of insulating material layers 80 and 81 have hydrophobic properties, thereby preventing aggregation between the semiconductor structures. The hydrophobic film may include a self-assembled monolayer (SAM), such as octadecyltrichlorosilane (OTS), fluoroalkyltrichlorosilane, or perfluoroalkyltriethoxysilane, a fluoropolymer, such as teflon or cytop, or a combination thereof, but is not limited thereto.

As a result of patterning the plurality of insulating material layers 80 and 81, the plurality of insulating layers 82 and 83 in contact with the side surfaces 71b and 72b of the plurality of first conductivity-type semiconductor layers 71 and 72, respectively, may be formed. At the same time, the plurality of insulating layers 82 and 83 may cover lower surfaces of the plurality of active layers 73 and 74, lower surfaces of the plurality of second conductivity-type semiconductor layers 75 and 76, and lower surfaces of the plurality of electrode layers 77 and 78.

In operation S107 of separating the plurality of first conductivity-type semiconductor layers 71 and 72 from the buffer layer 20, lower surfaces of the plurality of first conductivity-type semiconductor layers 71 and 72 may be separated from an upper surface of the buffer layer 20. Accordingly, each of the nanorod semiconductor structures separated from the buffer layer 20 may be substantially the same as the nanorod light-emitting diode 100 of FIG. 1.

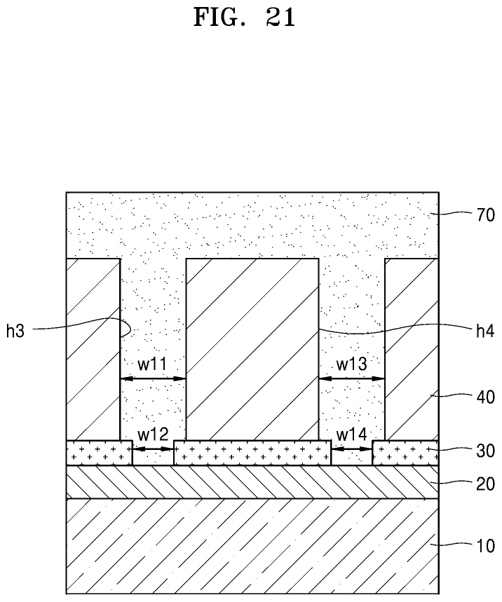

FIG. 21 is a view for explaining a method of manufacturing a nanorod light-emitting diode, according to another example embodiment.

The method of manufacturing a nanorod light-emitting diode, according to another example embodiment, which will be described with reference to FIG. 21, is substantially the same as the method of manufacturing a nanorod light-emitting diode, which is illustrated in FIG. 10, except that, in operation S103 of forming a plurality of first conductivity-type semiconductor material layers 70, a process temperature condition is further limited. Regarding FIG. 21, descriptions that are the same as those with respect to FIGS. 10 to 20 may be omitted.

Referring to FIG. 21, in operation S103 of forming the plurality of first conductivity-type semiconductor material layers 70 in the method of manufacturing a nanorod light-emitting diode, according to another example embodiment, the first conductivity-type semiconductor material layer 70 may be formed to fill a plurality of openings h3 and h4 and cover an upper surface of an oxide layer 40. The first conductivity-type semiconductor material layer 70 may include may include an n-type semiconductor of Group III-V, for example, an n-type nitride semiconductor. The first conductivity-type semiconductor material layer 70 may include a gallium element. The first conductivity-type semiconductor material layer 70 may include, for example, Alₓ₁In_{y1}G_{a1-x1-y1}N (0≤x1≤1, 0≤y1≤1, and 0≤(x1+y1)≤1). The first conductivity-type semiconductor material layer 70 may include InAlGaN, GaN, AlGaN, InGaN, AlN, InN, or a combination thereof. For example, the first conductivity-type semiconductor material layer 70 may include n-GaN.

The first conductivity-type semiconductor material layer 70 may be formed at a process temperature of about 1100° C. to about 1500° C. In this case, during a process of forming the first conductivity-type semiconductor material layer 70, a gallium element provided to an etch stop layer 30 may react with silicon included in the etch stop layer 30 to cause a meltback etching phenomenon. Accordingly, diameters w12 and w14 of lower regions of the first conductivity-type semiconductor material layer 70 adjacent to the etch stop layer 30 may be less than diameters w11 and w13 of central regions of the first conductivity-type semiconductor material layer 70 surrounded by the oxide layer 40.

A protrusion may be formed in a lower portion of the first conductive material layer 70 by the meltback etching phenomenon occurring during the process of forming the first conductivity-type semiconductor material layer 70. Thereafter, each of the nanorod semiconductor structures generated by sequentially performing operations S104, S105, S106, and S107 may be substantially the same as the nanorod light-emitting diode 110 of FIG. 3.

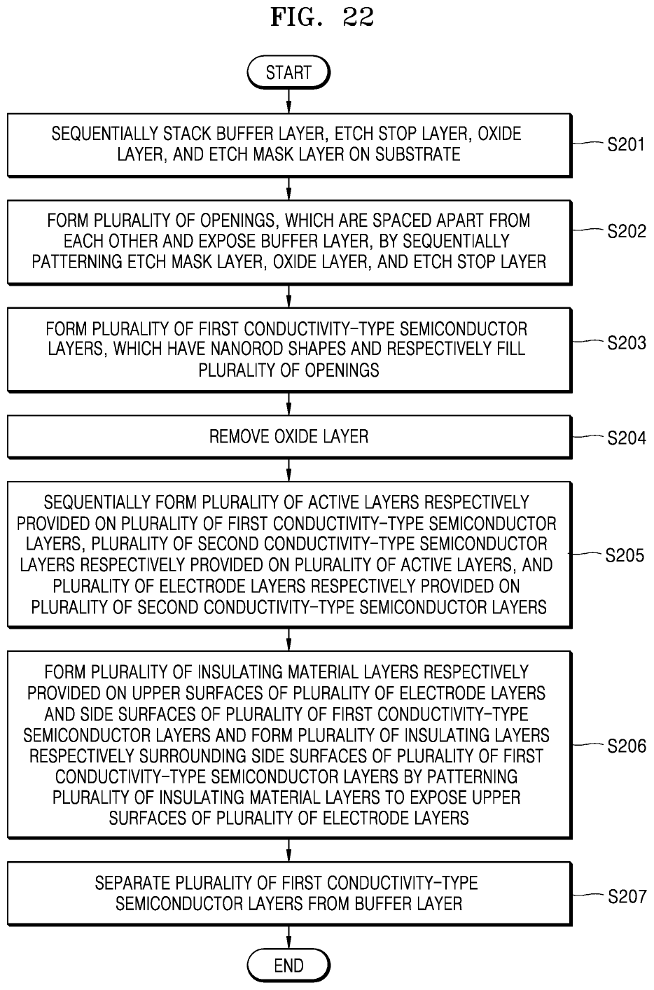

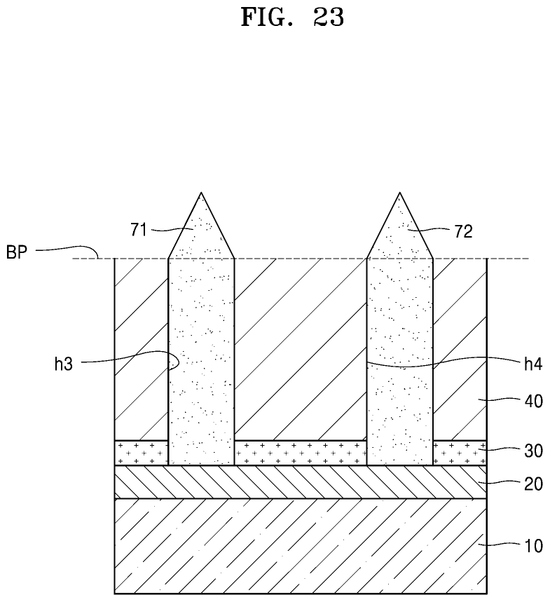

FIG. 22 is a flowchart illustrating a method of manufacturing a nanorod light-emitting diode, according to another example embodiment. FIGS. 23 to 26 are views for explaining the method of manufacturing a nanorod light-emitting diode, which is illustrated in FIG. 22.

Referring to FIG. 22, the method of manufacturing a nanorod light-emitting diode, according to another example embodiment, may include: operation S201 of sequentially stacking a buffer layer 20, an etch stop layer 30, an oxide layer 40, and an etch mask layer 50 on a substrate 10; operation S202 of forming a plurality of openings h3 and h4, which are apart from each other and expose the buffer layer 20, by sequentially patterning the etch mask layer 50, the oxide layer 40, and the etch stop layer 30; operation S203 of forming a first conductivity-type semiconductor material layer 70 filling the plurality of openings h3 and h4 and covering an upper surface of the oxide layer 40 and forming a plurality of first conductivity-type semiconductor layers 71 and 72, which have nanorod shapes and respectively fill the plurality of openings h3 and h4, by patterning the first conductivity-type semiconductor material layer 70; operation S204 of removing the oxide layer 40; and operation S205 of sequentially forming a plurality of active layers 84 and 85 respectively provided on the plurality of first conductivity-type semiconductor layers 71 and 72, a plurality of second conductivity-type semiconductor layers 86 and 87 respectively provided on the plurality of active layers 84 and 85, and a plurality of electrode layers 88 and 89 respectively provided on the plurality of second conductivity-type semiconductor layers 86 and 87. The method of manufacturing a nanorod light-emitting diode may further include: operation S206 of forming a plurality of insulating material layers 90 and 91 respectively provided on upper surfaces 88a and 89a of the plurality of electrode layers 88 and 89 and side surfaces 71b and 72b of the plurality of first conductivity-type semiconductor layers 71 and 72 and forming a plurality of insulating layers 92 and 93 respectively surrounding the side surfaces 71b and 72b of the plurality of first conductivity-type semiconductor layers 71 and 72 by patterning the plurality of insulating material layers 90 and 91 to expose the upper surfaces 88a and 89a of the plurality of electrode layers 88 and 89; and operation S207 of separating the plurality of first conductivity-type semiconductor layers 71 and 72 from the buffer layer 20.

Operations S201, S202, and S203 are substantially the same as operations S101, S102, and S103 of FIG. 10, and thus, detailed descriptions thereof may be omitted herein. Referring to FIG. 23, the plurality of first conductivity-type semiconductor layers 71 and 72, which have nanorod shapes and respectively fill the plurality of openings h3 and h4, may be formed through operations S201, S202, and S203. In this case, the first conductivity-type semiconductor material layer 70 may be patterned such that upper surfaces of the plurality of first conductivity-type semiconductor layers 71 and 72 are higher than the upper surface of the oxide layer 40 with respect to a reference plane BP parallel to the upper surface of the oxide layer 40.

For example, the first conductivity-type semiconductor material layer 70 may be patterned such that an upper portion of each of the plurality of first conductivity-type semiconductor layers 71 and 72 has a hexagonal pyramid shape. The hexagonal pyramid shape of each of the plurality of first conductivity-type semiconductor layers 71 and 72 may be positioned higher than the upper surface of the oxide layer 40 with respect to the reference plane BP.

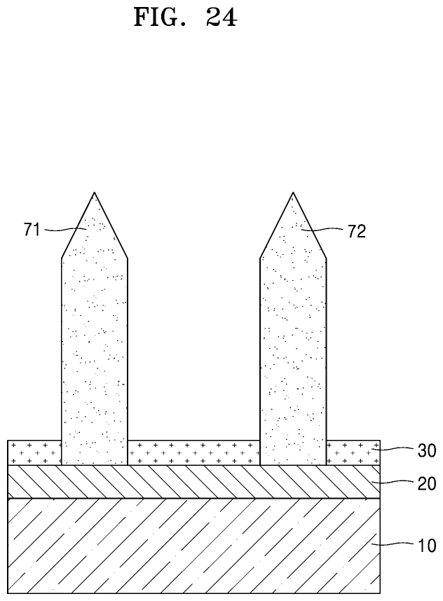

Referring to FIG. 24, in operation S204 of removing the oxide layer 40, the oxide layer 40 surrounding the side surfaces of the plurality of first conductivity-type semiconductor layers 71 and 72 may be removed. In this case, the oxide layer 40 may be removed through a wet process using a buffered oxide etchant (BOE) solution, an LAL solution (combination of NH₄F, HF and H₂O), hydrogen fluoride (HF), or the like.

As the oxide layer 40 is removed in operation S204, both upper surfaces and side surfaces of the plurality of first conductivity-type semiconductor layers 71 and 72 may be exposed to the outside.

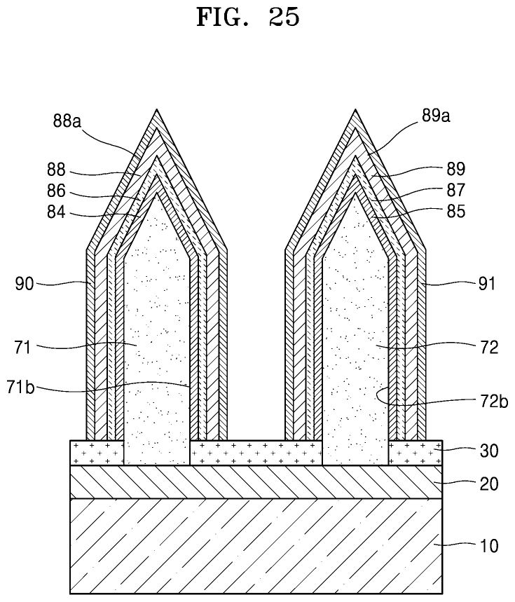

Referring to FIG. 25, in operation S205, the plurality of active layers 84 and 85, the plurality of second conductivity-type semiconductor layers 86 and 87, the plurality of electrode layers 88 and 89, and the plurality of insulating material layers 90 and 91 may be sequentially formed on the plurality of first conductivity-type semiconductor layers 71 and 72 by using an epitaxial growth method, such MOCVD, MBE, or HPVE.

First, the plurality of active layers 84 and 85 respectively covering upper surfaces and side surfaces 71b and 72b of the plurality of first conductivity-type semiconductor layers 71 and 72 may be formed. For example, the plurality of active layers 84 and 85 may respectively cover the upper surfaces of hexagonal pyramid shapes respectively formed in upper portions of the plurality of first conductivity-type semiconductor layers 71 and 72. In this case, the cross-sections of upper regions of the plurality of active layers 84 and 85 may respectively have V-shapes corresponding to hexagonal pyramid-shaped upper regions of the plurality of first conductivity-type semiconductor layers 71 and 72.

Light may be generated while electrons and holes are combined in the plurality of active layers 84 and 85. Each of the plurality of active layers 84 and 85 may have an MQW structure or an SQW structure. Each of the plurality of active layers 84 and 85 may include a semiconductor of Group III-V. Each of the plurality of active layers 84 and 85 may include Alₓ₂In_{y2}Ga_{1-x2-y2}N (0.1≤(x2+y2)≤1 and 0.1<y2<0.6), and may include, for example, GaN.

The plurality of second conductivity-type semiconductor layers 86 and 87, which respectively cover upper surfaces of the plurality of active layers 84 and 85, may be formed. In this case, upper regions of the plurality of second conductivity-type semiconductor layers 86 and 87 may respectively have V-shaped cross-sections corresponding to the structures of the plurality of active layers 84 and 85 covering the hexagonal pyramid shapes formed in upper portions of the plurality of first conductivity-type semiconductor layers 71 and 72.

Each of the plurality of second conductivity-type semiconductor layers 86 and 87 may include, for example, a p-type semiconductor. Each of the plurality of second conductivity-type semiconductor layers 86 and 87 may include a p-type semiconductor of Group III-V. For example, each of the plurality of second conductivity-type semiconductor layers 86 and 87 may include Alₓ₁In_{y1}Ga_{1-x1-y1}N (0≤x1≤1, 0≤y1≤1, and 0≤(x1+y1)≤1). Each of the plurality of second conductivity-type semiconductor layers 86 and 87 may include InAlGaN, GaN, AlGaN, InGaN, AlN, InN, or a combination thereof. For example, each of the plurality of second conductivity-type semiconductor layers 86 and 87 may include p-GaN. Each of the plurality of second conductivity-type semiconductor layers 86 and 87 may have a single-layer or multi-layer structure. Each of the plurality of second conductivity-type semiconductor layers 86 and 87 may include a second conductivity-type dopant. Each of the plurality of second conductivity-type semiconductor layers 86 and 87 may include a p-type dopant, for example, Mg, B, or the like.

The plurality of electrode layers 88 and 89 may be formed to cover upper surfaces and side surfaces of the plurality of second conductivity-type semiconductor layers 86 and 87, respectively. In this case, upper regions of the plurality of electrode layers 88 and 89 may respectively have V-shaped cross-sections corresponding to the structures of the plurality of active layers 84 and 85 covering the hexagonal pyramid shapes formed on the plurality of first conductivity-type semiconductor layers 71 and 72.

Each of the plurality of electrode layers 88 and 89 may include a conductive material. Each of the plurality of electrode layers 88 and 89 may include a transparent conductive material. For example, each of the plurality of electrode layers 88 and 89 may include ITO, ZnO, or the like. In addition, each of the plurality of electrode layers 88 and 89 may include Cr, Ti, Pt, Al, Au, Ni, an oxide or alloy thereof, or a mixture thereof, but is not limited thereto.

In addition, in operation S206 of forming the plurality of insulating layers 92 and 93, the plurality of insulating material layers 90 and 91 covering the upper surfaces and side surfaces of the plurality of electrode layers 88 and 89, respectively, may be formed. In this case, upper regions of the plurality of insulating material layers 90 and 91 may respectively have V-shaped cross-sections corresponding to the structures of the plurality of active layers 84 and 85 covering the hexagonal pyramid shapes formed in upper portions of the plurality of first conductivity-type semiconductor layers 71 and 72.

The plurality of insulating material layers 90 and 91 may be formed by an ALD method, but is not limited thereto and may also be formed by a PECVD method. The plurality of insulating material layers 90 and 91 may include, for example, Al₂O₃, HfO₂, SiO₂, or SiN. The thickness of the plurality of insulating material layers 90 and 91 may be several nm to several hundreds of nm.

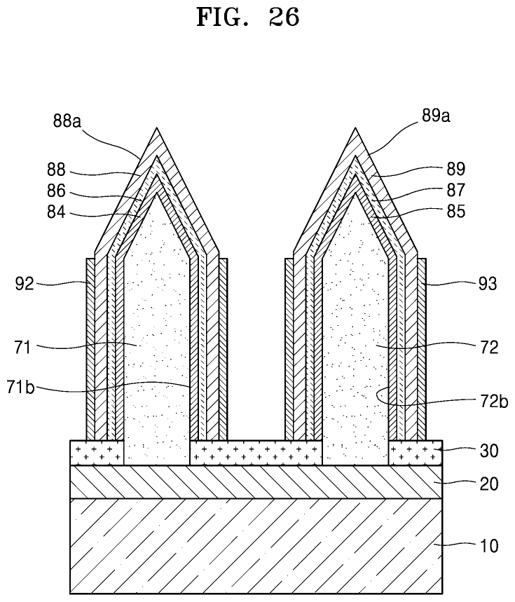

Furthermore, in operation S206 of forming the plurality of insulating layers 92 and 93, referring to FIG. 26, the plurality of insulating material layers 90 and 91 may be patterned to expose the upper surfaces 88a and 89a of the plurality of electrode layers 88 and 89, respectively. In this case, the plurality of insulating material layers 90 and 91 may be patterned using an anisotropic etch back method. In this process, a hydrophobic film may be further formed on the plurality of insulating material layers 90 and 91. The hydrophobic film may make semiconductor structure surrounded by the plurality of insulating material layers 90 and 91 have hydrophobic properties, thereby preventing aggregation between the semiconductor structures. The hydrophobic film may include an SAM, such as OTS, fluoroalkyltrichlorosilane, or perfluoroalkyltriethoxysilane, a fluoropolymer, such as teflon or cytop, or a combination thereof, but is not limited thereto.

As a result of patterning the plurality of insulating material layers 90 and 91, the plurality of insulating layers 92 and 93 in contact with the side surfaces of the plurality of electrode layers 88 and 89 surrounding the side surfaces 71b and 72b of the plurality of first conductivity-type semiconductor layers 71 and 72, respectively, may be formed.

In operation S207, lower surfaces of the plurality of first conductivity-type semiconductor layers 71 and 72 may be separated from an upper surface of the buffer layer 20. Accordingly, each of the nanorod semiconductor structures separated from the buffer layer 20 may be substantially the same as the nanorod light-emitting diode 120 of FIG. 4.

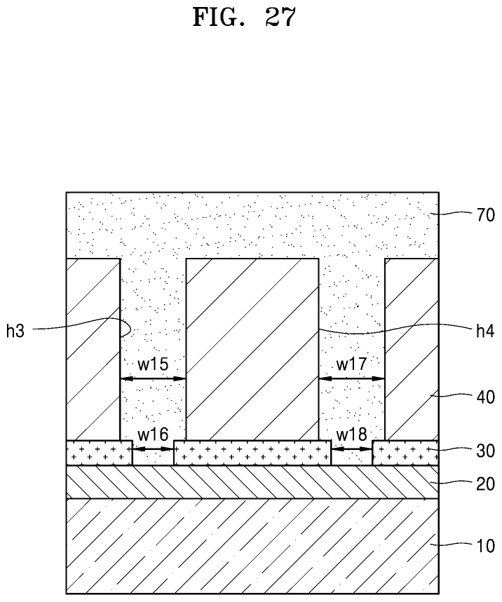

FIG. 27 is a view for explaining a method of manufacturing a nanorod light-emitting diode, according to another example embodiment.

The method of manufacturing a nanorod light-emitting diode, according to another example embodiment, which will be described with reference to FIG. 27, is substantially the same as the method of manufacturing a nanorod light-emitting diode, which is illustrated in FIG. 22, except that, in operation S203 of forming a plurality of first conductivity-type semiconductor material layers 70, a process temperature condition is further limited. Regarding FIG. 27, descriptions that are the same as those with respect to FIGS. 22 to 26 may be omitted.

Referring to FIG. 27, in operation S203 of forming the plurality of first conductivity-type semiconductor material layers 70 in the method of manufacturing a nanorod light-emitting diode, according to another example embodiment, the first conductivity-type semiconductor material layer 70 may be formed to fill a plurality of openings h3 and h4 and cover an upper surface of an oxide layer 40. The first conductivity-type semiconductor material layer 70 may include may include an n-type semiconductor of Group III-V, for example, an n-type nitride semiconductor. The first conductivity-type semiconductor material layer 70 may include a gallium element. The first conductivity-type semiconductor material layer 70 may include, for example, Alₓ₁In_{y1}G_{a1-x1-y1}N (0≤x1≤1, 0≤y1≤1, and 0≤(x1+y1)≤1). The first conductivity-type semiconductor material layer 70 may include InAlGaN, GaN, AlGaN, InGaN, AlN, InN, or a combination thereof. For example, the first conductivity-type semiconductor material layer 70 may include n-GaN.

The first conductivity-type semiconductor material layer 70 may be formed at a process temperature of about 1100° C. to about 1500° C. In this case, during a process of forming the first conductivity-type semiconductor material layer 70, a gallium element provided to an etch stop layer 30 may react with silicon included in the etch stop layer 30 to cause a meltback etching phenomenon. Accordingly, diameters w12 and w14 of lower regions of the first conductivity-type semiconductor material layer 70 adjacent to the etch stop layer 30 may be less than diameters w11 and w13 of central regions of the first conductivity-type semiconductor material layer 70 surrounded by the oxide layer 40.

A protrusion may be formed in a lower portion of the first conductive material layer 70 by the meltback etching phenomenon occurring during the process of forming the first conductivity-type semiconductor material layer 70. Thereafter, each of the nanorod semiconductor structures generated by sequentially performing operations S204, S205, S206, and S207 may be substantially the same as the nanorod light-emitting diode 130 of FIG. 6.

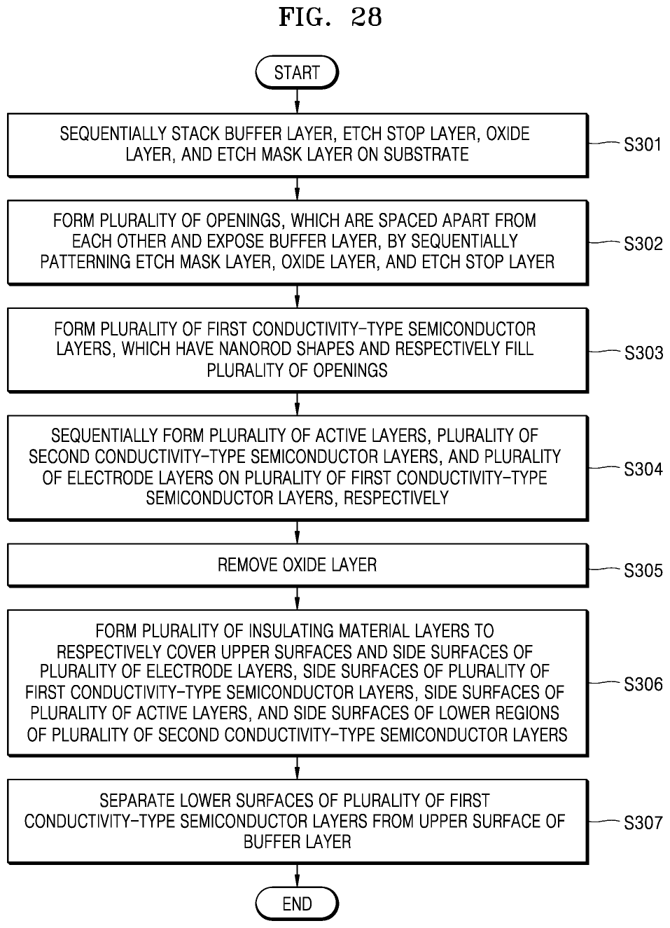

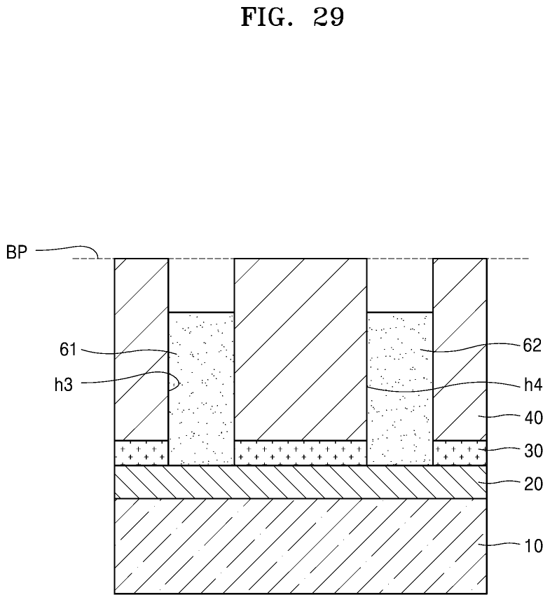

FIG. 28 is a flowchart illustrating a method of manufacturing a nanorod light-emitting diode, according to another example embodiment. FIGS. 29 to 33 are views for explaining the method of manufacturing a nanorod light-emitting diode, which is illustrated in FIG. 28.

Operations S301 and S302 are substantially the same as operations S101 and S102 of FIG. 10, and thus, detailed description thereof may be omitted herein.

Referring to FIG. 29, a plurality of first conductivity-type semiconductor layers 61 and 62, which have nanorod shapes and respectively fill a plurality of openings h3 and h4, may be formed in operation S303. In this case, the plurality of first conductivity-type semiconductor layers 61 and 62 may be formed by patterning a first conductivity-type semiconductor material layer 70 such that upper surfaces of the plurality of first conductivity-type semiconductor layers 61 and 62 are positioned lower than an upper surface of an oxide layer 40 with respect to a reference plane BP parallel to the upper surface of the oxide layer 40. In this case, upper surfaces of the plurality of first conductivity-type semiconductor layers 61 and 62 may be formed to be flat.

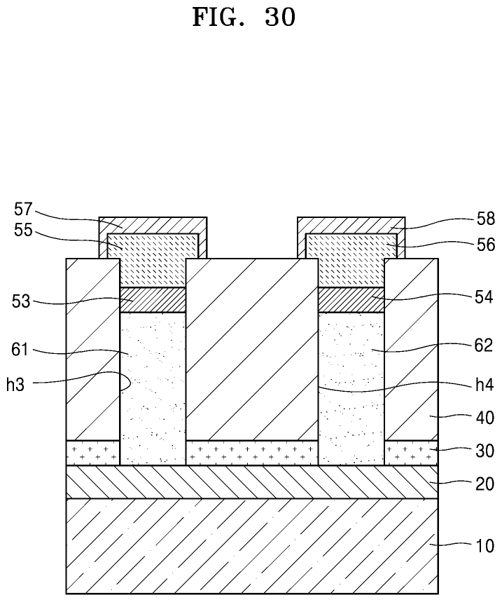

Referring to FIG. 30, in operation S304, a plurality of active layers 53 and 54, a plurality of second conductivity-type semiconductor layers 55 and 56, and a plurality of electrode layers 57 and 58 may be sequentially formed on the plurality of first conductivity-type semiconductor layers 61 and 62 by using an epitaxial growth method, such MOCVD, MBE, or HPVE.

First, the plurality of active layers 53 and 54 respectively covering upper surfaces of the plurality of first conductivity-type semiconductor layers 61 and 62 may be formed. In this case, lower surfaces of the plurality of active layers 53 and 54 may be formed to be flat to correspond to the upper surfaces of the plurality of first conductivity-type semiconductor layers 61 and 62. The plurality of active layers 53 and 54 may be provided to fill portions of the plurality of openings h3 and h4, respectively.

The plurality of active layers 53 and 54 may have hexagonal column shapes. In this case, the active layers 53 and 54 may have hexagonal cross-sections when viewed from above.

Light may be generated while electrons and holes are combined in the plurality of active layers 53 and 54. Each of the plurality of active layers 53 and 54 may have an MQW structure or an SQW structure. Each of the plurality of active layers 53 and 54 may include a semiconductor of Group III-V. Each of the plurality of active layers 53 and 54 may include Alₓ₂In_{y2}Ga_{1-x2-y2}N (0.1≤(x2+y2)≤1 and 0.1<y2<0.6), and may include, for example, GaN.

The plurality of second conductivity-type semiconductor layers 55 and 56, which respectively cover upper surfaces of the plurality of active layers 53 and 54, may be formed. In this case, lower surfaces of the plurality of second conductivity-type semiconductor layers 55 and 56 may be formed to be flat to correspond to the upper surface of the plurality of active layers 53 and 54. The plurality of second conductivity-type semiconductor layers 55 and 56 may have hexagonal column shapes. In this case, the plurality of second conductivity-type semiconductor layers 55 and 56 may have hexagonal cross-sections in a top view of the nanorod light-emitting diode 140.

Also, the plurality of second conductivity-type semiconductor layers 55 and 56 may have T-shapes. Accordingly, the diameters of the lower surfaces of the plurality of second conductivity-type semiconductor layers 55 and 56, which are in contact with the upper surfaces of the plurality of active layers 53 and 54, may be less than those of the upper surfaces of the plurality of second conductivity-type semiconductor layers 55 and 56. Upper regions of the plurality of second conductivity-type semiconductor layers 55 and 56 having T-shapes may extend in left and right directions to cover a portion of an oxide layer 40.

Each of the plurality of second conductivity-type semiconductor layers 55 and 56 may include, for example, a p-type semiconductor. Each of the plurality of second conductivity-type semiconductor layers 55 and 56 may include a p-type semiconductor of Group III-V. For example, each of the plurality of second conductivity-type semiconductor layers 55 and 56 may include Alₓ₁In_{y1}Ga_{1-x1-y1}N (0≤x1≤1, 0≤y1≤1, and 0≤(x1+y1)≤1). Each of the plurality of second conductivity-type semiconductor layers 55 and 56 may include InAlGaN, GaN, AlGaN, InGaN, AlN, InN, or a combination thereof. For example, each of the plurality of second conductivity-type semiconductor layers 55 and 56 may include p-GaN. Each of the plurality of second conductivity-type semiconductor layers 55 and 56 may have a single-layer or multi-layer structure. Each of the plurality of second conductivity-type semiconductor layers 55 and 56 may include a second conductivity-type dopant. Each of the plurality of second conductivity-type semiconductor layers 55 and 56 may include a p-type dopant, for example, Mg, B, or the like.

The plurality of electrode layers 57 and 58 may be formed to cover upper surfaces of the plurality of second conductivity-type semiconductor layers 55 and 56, respectively. Also, the plurality of electrode layers 57 and 58 may cover side surfaces of upper regions of the plurality of second conductivity-type semiconductor layers 55 and 56 having T-shapes. Accordingly, the upper surfaces and side surfaces of the upper regions of the plurality of second conductivity-type semiconductor layers 55 and 56 having relatively larger diameters than those of lower regions of the plurality of second conductivity-type semiconductor layers 55 and 56 may be covered by the plurality of electrode layers 57 and 58, respectively.

Each of the plurality of electrode layers 57 and 58 may include a conductive material. Each of the plurality of electrode layers 57 and 58 may include a transparent conductive material. For example, each of the plurality of electrode layers 57 and 58 may include ITO, ZnO, or the like. In addition, each of the plurality of electrode layers 57 and 58 may include Cr, Ti, Pt, Al, Au, Ni, an oxide or alloy thereof, or a mixture thereof, but is not limited thereto.

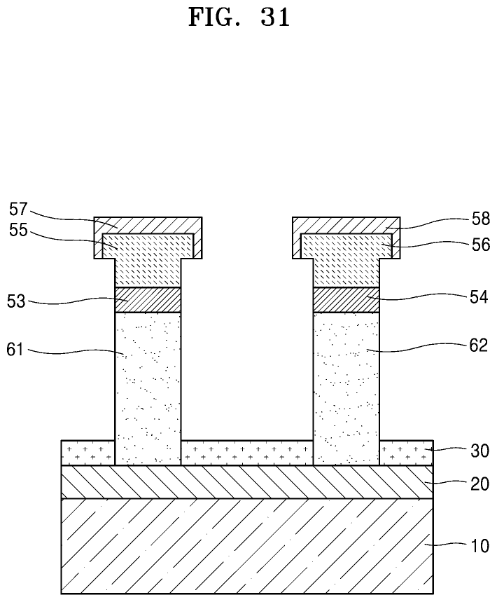

Referring to FIG. 31, in operation S305, the oxide layer 40, which surrounds the side surfaces of the plurality of first conductivity-type semiconductor layers 61 and 62, the plurality of active layers 53 and 54, and lower regions of the plurality of second conductivity-type semiconductor layers 55 and 56, may be removed. In this case, the oxide layer 40 may be removed through a wet process using a buffered oxide etchant (BOE) solution, an LAL solution (combination of NH₄F, HF and H₂O), hydrogen fluoride (HF), or the like.

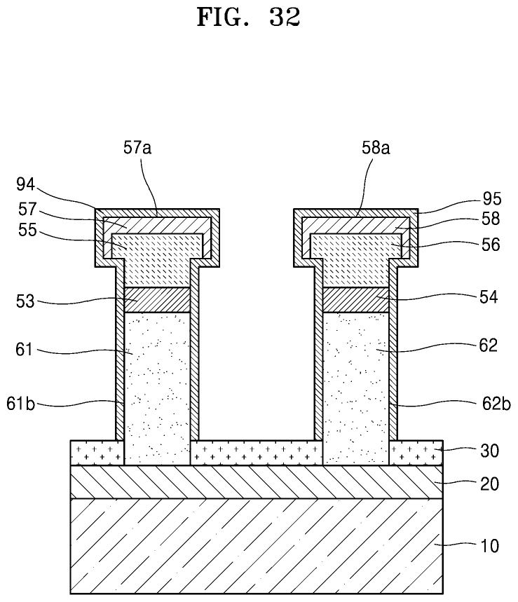

Referring to FIG. 32, in operation S306, a plurality of insulating material layers 94 and 95 may be formed to respectively cover the upper surfaces and side surfaces of the plurality of electrode layers 57 and 58, the side surfaces of the plurality of first conductivity-type semiconductor layers 61 and 62, the side surfaces of the plurality of active layers 53 and 54, and the side surfaces of the lower regions of the plurality of second conductivity-type semiconductor layers 55 and 56.

The plurality of insulating material layers 94 and 95 may be formed by an ALD method, but is not limited thereto and may also be formed by a PECVD method. The plurality of insulating material layers 94 and 95 may include, for example, Al₂O₃, HfO₂, SiO₂, or SiN. The thickness of the plurality of insulating material layers 94 and 95 may be several nm to several hundreds of nm.

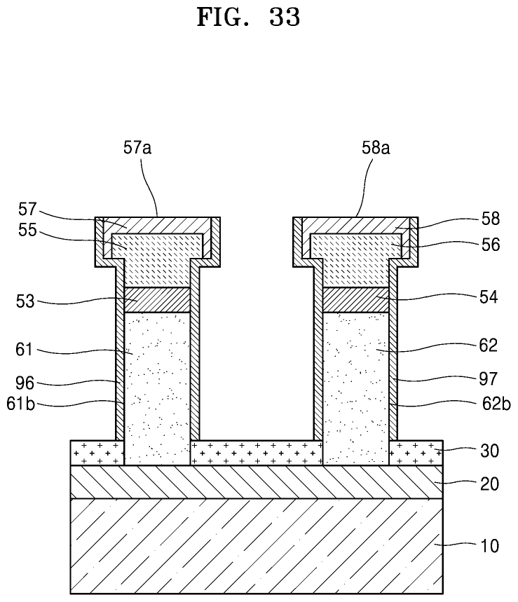

Furthermore, referring to FIG. 33, the plurality of insulating material layers 94 and 95 may be patterned to expose upper surfaces 57a and 58a of the plurality of electrode layers 57 and 58, respectively. In this case, the plurality of insulating material layers 94 and 95 may be patterned using an anisotropic etch back method. In this process, a hydrophobic film may be further formed on the plurality of insulating material layers 94 and 95. The hydrophobic film may make semiconductor structure surrounded by the plurality of insulating material layers 94 and 95 have hydrophobic properties, thereby preventing aggregation between the semiconductor structures. The hydrophobic film may include an SAM, such as OTS, fluoroalkyltrichlorosilane, or perfluoroalkyltriethoxysilane, a fluoropolymer, such as teflon or cytop, or a combination thereof, but is not limited thereto.

As a result of patterning the plurality of insulating material layers 94 and 95, a plurality of insulating layers 96 and 97 may be formed to respectively cover the side surfaces 61b and 62b of the plurality of first conductivity-type semiconductor layers 61 and 62, the side surfaces of the plurality of active layers 53 and 54, and the side surfaces of the lower regions of the plurality of second conductivity-type semiconductor layers 55 and 56.

In operation S307, lower surfaces of the plurality of first conductivity-type semiconductor layers 61 and 62 may be separated from an upper surface of the buffer layer 20. Accordingly, each of the nanorod semiconductor structures separated from the buffer layer 20 may be substantially the same as the nanorod light-emitting diode 140 of FIG. 7.

Furthermore, in a method of manufacturing a nanorod light-emitting diode, according to another example embodiment, which is substantially the same as the method of manufacturing a nanorod light-emitting diode, illustrated in FIG. 28, except that, in operation S303 of forming a plurality of first conductivity-type semiconductor material layers 61 and 62, a process temperature condition is further limited, the first conductivity-type semiconductor material layers 61 and 62 may be formed at a process temperature of about 1100° C. to about 1500° C. In this case, during a process of forming the first conductivity-type semiconductor layers 61 and 62, a gallium element provided to an etch stop layer 30 may react with silicon included in the etch stop layer 30 to cause a meltback etching phenomenon.

Protrusions may be formed in lower portions of the first conductivity-type semiconductor layers 61 and 62 by the meltback etching phenomenon occurring during the process of forming the first conductivity-type semiconductor material layers 61 and 62. Thereafter, each of the nanorod semiconductor structures generated by sequentially performing operations S304, S305, S306, and S307 may be substantially the same as the nanorod light-emitting diode 150 of FIG. 9.

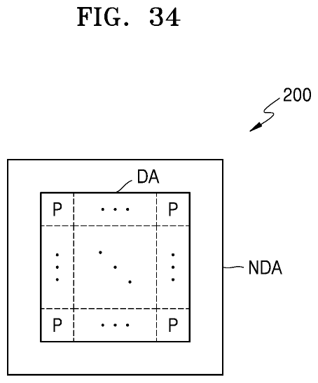

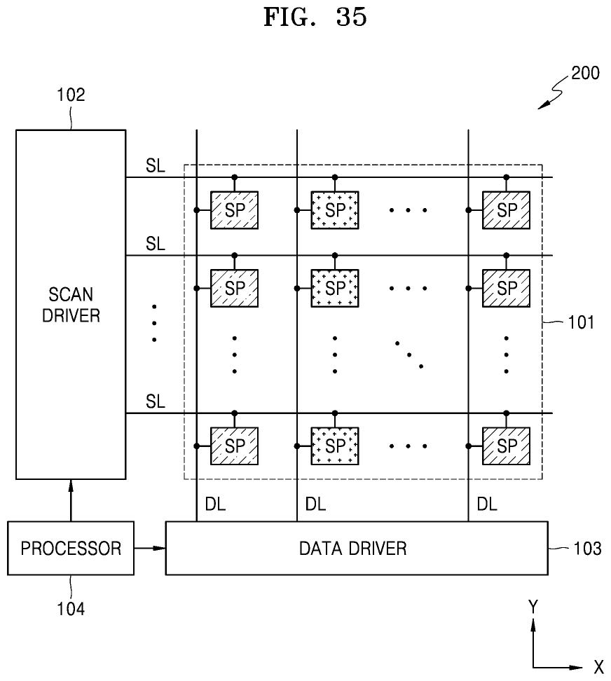

FIG. 34 is a schematic conceptual view of a display apparatus 200 according to an example embodiment. FIG. 35 is a schematic circuit diagram of the display apparatus 200 according to an example embodiment.

Referring to FIGS. 34 and 35, the display apparatus 200 may be divided into a display area DA and a non-display area NDA. The display area DA is an area for displaying an image. The display area DA may include a plurality of pixels P for displaying an image. The plurality of pixels P may be arranged in the form of a two-dimensional array in the display area DA. Each of the plurality of pixels P may include sub-pixels SP emitting light of different colors.

Also, the display apparatus 200 may include a pixel array 101, a scan driver 102, a data driver 103, and a processor 104. The pixel array 101 may be disposed in the display area DA of the display apparatus 200. On the other hand, the scan driver 102, the data driver 103, and the processor 104 may be disposed in the non-display area NDA of the display apparatus 200.

The pixel array 101 may include a plurality of pixels P or a plurality of sub-pixels SP arranged in a two-dimensional array form, a plurality of scan lines SL for transferring scan signals to the plurality of pixels P or the plurality of sub-pixels SP, and a plurality of data lines DL for transferring data signals to the plurality of pixels P or the plurality of sub-pixels SP. The plurality of scan lines SL extend toward the scan driver 102 to receive the scan signals from the scan driver 102, and the plurality of data lines DL extend toward the data driver 103 to receive the data signals from the data driver 103.

The plurality of scan lines SL and the plurality of data lines DL respectively extend in directions crossing each other. FIG. 32 illustrates an example in which the plurality of scan lines SL extend in an X direction and the plurality of data lines DL extend in a Y direction. However, the disclosure is not limited thereto, and an extension direction of the plurality of data lines DL and an extension direction of the plurality of scan lines SL may be interchanged with each other. Sub-pixels SP may be respectively disposed at positions where the plurality of scan lines SL intersect the plurality of data lines DL.

Each of the plurality of sub-pixels SP may include a light-emitting element, i.e., a light-emitting diode, and a driving transistor for driving the light-emitting element. The light-emitting element may be a micro light-emitting element having a micro-scale size. For example, the light-emitting element in each of the plurality of sub-pixels SP may include various types of nanorod light-emitting diodes 100, 110, 120, 130, 140, and 150 described with reference to FIGS. 1 to 9. According to an example embodiment, the light-emitting element and the driving transistor may be formed together on one growth substrate. The display apparatus 200 described above may be applied to various electronic devices having screen display functions.

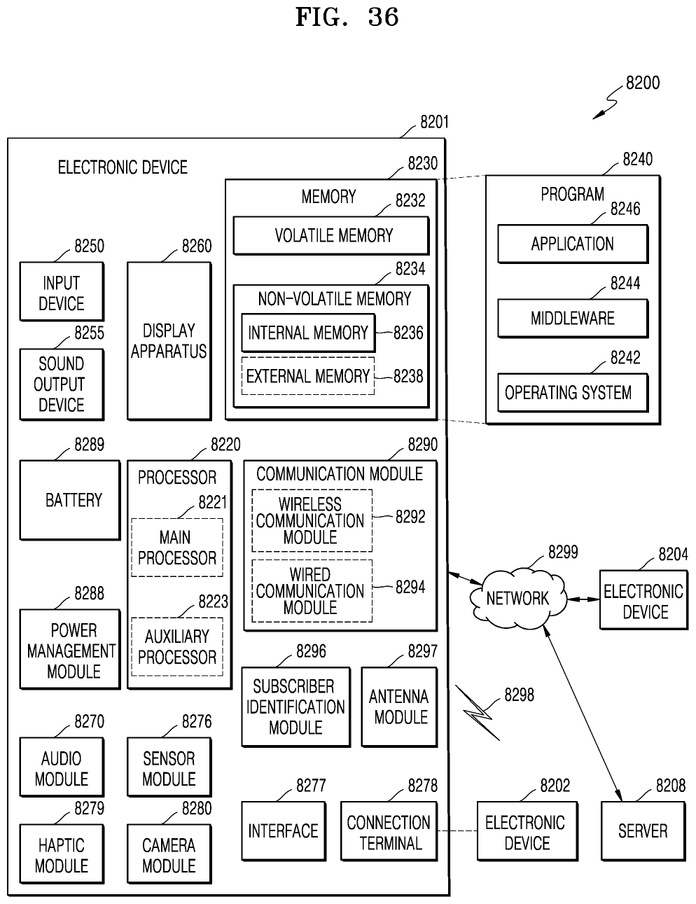

FIG. 36 is a block diagram of an electronic device 8201 according to an example embodiment.

Referring to FIG. 36, the electronic device 8201 may be provided in a network environment 8200. In the network environment 8200, the electronic device 8201 may communicate with another electronic device 8202 through a first network 8298 (a short-range wireless communication network, etc.) or with another electronic device 8204 and/or a server 8208 through a second network 8299 (a remote wireless communication network, etc.). The electronic device 8201 may communicate with the electronic device 8204 through the server 8208. The electronic device 8201 may include a processor 8220, a memory 8230, an input device 8250, a sound output device 8255, a display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. The electronic device 8201 may omit some of these components or may further include other components. Some of these components may be implemented as an integrated circuit. For example, the sensor module 8276 (a fingerprint sensor, an iris sensor, an illuminance sensor, etc.) may be embedded in the display apparatus 8260 (a display, etc.)

The processor 8220 may execute software (a program 8240, etc.) to control one or more components (hardware, software, etc.) of the electronic device 8201 connected to the processor 8220 and to perform various data processing or computation operations. As part of the data processing or computation operations, the processor 8220 may be configured to load a command and/or data received from other components (the sensor module 8276, the communication module 8290, etc.) into a volatile memory 8232, process the command and/or the data stored in the volatile memory 8232, and store resulting data in a non-volatile memory 8234. The non-volatile memory 8234 may include an internal memory 8236 mounted in the electronic device 8201 and a removable external memory 8238. The processor 8220 may include a main processor 8221 (a central processing unit, an application processor, etc.) and an auxiliary processor 8223 (a graphics processing unit, an image signal processor, a sensor-hub processor, a communication processor, etc.) which may operate separately from or together with the main processor 8221. The auxiliary processor 8223 may use less power than the main processor 8221 and may perform specialized functions.

The auxiliary processor 8223 may operate instead of the main processor 8221, when the main processor 8221 is in an inactive state (a sleep state), may operate together with the main processor 8221, when the main processor 8221 is in an active state (an application execution state), and may control a function and/or a state associated with one or more components (the display apparatus 8260, the sensor module 8276, the communication module 8290, etc.) of the electronic device 8201. The auxiliary processor 8223 (the image signal processor, the communication processor, etc.) may be implemented as part of other functionally related components (the camera module 8280, the communication module 8290, etc.).

The memory 8230 may store various data required by the components (the processor 8220, the sensor module 8276, etc.) of the electronic device 8201. The data may include, for example, the software (the program 8240, etc.), and input data and/or output data with respect to a command related to the software. The memory 8230 may include the volatile memory 8232 and/or the non-volatile memory 8234.

The program 8240 may be stored in the memory 8230 as software and may include an operating system 8242, middleware 8244, and/or an application 8246.

The input device 8250 may receive a command and/or data to be used for the components (the processor 8220, etc.) of the electronic device 8201, from the outside (a user, etc.) of the electronic device 8201. The input device 8250 may include a remote controller, a microphone, a mouse, a keyboard, and/or a digital pen (a stylus pen, etc.).

The sound output device 8255 may output a sound signal to the outside of the electronic device 8201. The sound output device 8255 may include a speaker and/or a receiver. The speaker may be used for a general purpose, such as reproducing multimedia content or recording content, and the receiver may be used to receive an incoming call. The receiver may be integrated as part of the speaker or separately provided from the speaker.

The display apparatus 8260 may visually provide data to the outside of the electronic device 8201. The display apparatus 8260 may include a display, a hologram device, or a control circuit configured to control a projector and a corresponding device. The display apparatus 8260 may be the display apparatus 200 having the above-described structure. The display apparatus 8260 may further include touch circuitry configured to sense a touch operation and/or sensor circuitry (a pressure sensor, etc.) configured to measure an intensity of a force generated by the touch operation.

The audio module 8270 may convert sound into an electrical signal or an electrical signal into sound. The audio module 8270 may obtain sound via the input device 8250 or may output sound via the sound output device 8255 and/or a speaker and/or a headphone of another electronic device (the electronic device 8202, etc.) directly or wirelessly connected to the electronic device 8201.

The sensor module 8276 may sense an operation state (power, temperature, etc.) of the electronic device 8201 or an external environmental state (a user state, etc.) and generate electrical signals and/or data values corresponding to the sensed state. The sensor module 8276 may include a gesture sensor, a gyro-sensor, an atmospheric sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more designated protocols to be used for the electronic device 8201 to be directly or wirelessly connected to another electronic device (the electronic device 8202, etc.). The interface 8277 may include a high-definition multimedia interface (HDMI) interface, a universal serial bus (USB) interface, an SD card interface, and/or an audio interface.

A connection terminal 8278 may include a connector, through which the electronic device 8201 may be physically connected to another electronic device (the electronic device 8202, etc.). The connection terminal 8278 may include an HDMI connector, a USB connector, an SD card connector, and/or an audio connector (a headphone connector, etc.).

The haptic module 8279 may convert an electrical signal into a mechanical stimulus (vibration, motion, etc.) or an electrical stimulus which is recognizable to a user via haptic or motion sensation. The haptic module 8279 may include a motor, a piezoelectric device, and/or an electrical stimulus device.

The camera module 8280 may capture a still image and a video. The camera module 8280 may include a lens assembly including one or more lenses, image sensors, image signal processors, and/or flashes. The lens assemblies included in the camera module 8280 may collect light emitted from an object, an image of which is to be captured.

The power management module 8288 may manage power supplied to the electronic device 8201. The power management module 8288 may be realized as part of a power management integrated circuit (PMIC).

The battery 8289 may supply power to the components of the electronic device 8201. The battery 8289 may include a non-rechargeable primary battery, rechargeable secondary battery, and/or a fuel battery.

The communication module 8290 may support establishment of direct (wired) communication channels and/or wireless communication channels between the electronic device 8201 and other electronic devices (the electronic device 8202, the electronic device 8204, the server 8208, etc.) and communication performance through the established communication channels. The communication module 8290 may include one or more communication processors separately operating from the processor 8220 (an application processor, etc.) and supporting direct communication and/or wireless communication. The communication module 8290 may include a wireless communication module 8292 (a cellular communication module, a short-range wireless communication module, a global navigation satellite system (GNSS) communication module, and/or a wired communication module 8294 (a local area network (LAN) communication module, a power line communication module, etc.). From these communication modules, a corresponding communication module may communicate with other electronic devices through the first network 8298 (a short-range wireless communication network, such as Bluetooth, Wifi direct, or infrared data association (IrDa)) or the second network 8299 (a remote communication network, such as a cellular network, the Internet, or a computer network (LAN, WAN, etc.)). Various types of communication modules described above may be integrated as a single component (a single chip, etc.) or realized as a plurality of components (a plurality of chips). The wireless communication module 8292 may identify and authenticate the electronic device 8201 within the first network 8298 and/or the second network 8299 by using subscriber information (international mobile subscriber identification (IMSI), etc.) stored in the subscriber identification module 8296.

The antenna module 8297 may transmit a signal and/or power to the outside (other electronic devices, etc.) or receive the same from the outside. The antenna may include an emitter including a conductive pattern formed on a substrate (a printed circuit board (PCB), etc.). The antenna module 8297 may include an antenna or a plurality of antennas. When the antenna module 8297 includes a plurality of antennas, an appropriate antenna which is suitable for a communication method used in the communication networks, such as the first network 8298 and/or the second network 8299, may be selected. Through the selected antenna, signals and/or power may be transmitted or received between the communication module 8290 and other electronic devices. In addition to the antenna, another component (a radio frequency integrated circuit (RFIC), etc.) may be included in the antenna module 8297.

Some of the components of the electronic device 8201 may be connected to one another and exchange signals (commands, data, etc.) with one another, through communication methods performed among peripheral devices (a bus, general purpose input and output (GPIO), a serial peripheral interface (SPI), a mobile industry processor interface (MIPI), etc.).

The command or the data may be transmitted or received between the electronic device 8201 and another external electronic device 8204 through the server 8208 connected to the second network 8299. The other electronic devices 8202 and 8204 may be electronic devices that are homogeneous or heterogeneous types with respect to the electronic device 8201. All or part of operations performed in the electronic device 8201 may be performed by one or more of the other electronic devices 8202, 8204, and 8208. For example, when the electronic device 8201 has to perform a function or a service, instead of directly performing the function or the service, the one or more other electronic devices may be requested to perform part or all of the function or the service. The one or more other electronic devices receiving the request may perform an additional function or service related to the request and may transmit a result of the execution to the electronic device 8201. To this end, cloud computing, distribution computing, and/or client-server computing techniques may be used.

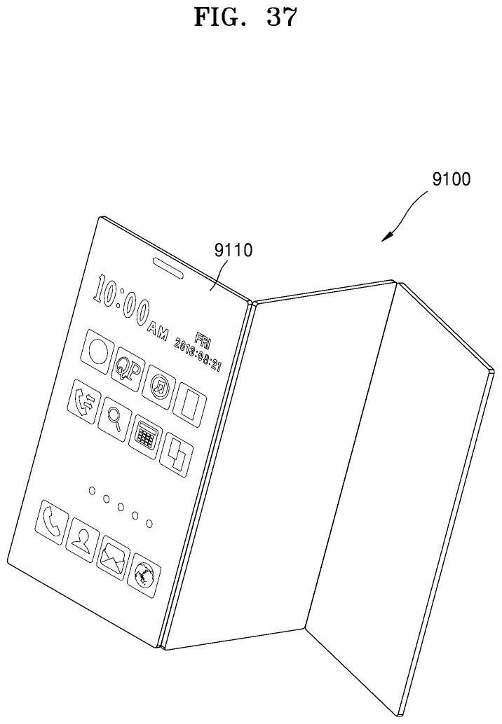

FIG. 37 illustrates an example in which a display apparatus according to an example embodiment is applied to a mobile device 9100. The mobile device 9100 may include a display apparatus 9110, and the display apparatus 9110 may be the display apparatus 200 having the above-described structure. The display apparatus 9110 may have a foldable structure, for example, a multi-foldable structure.

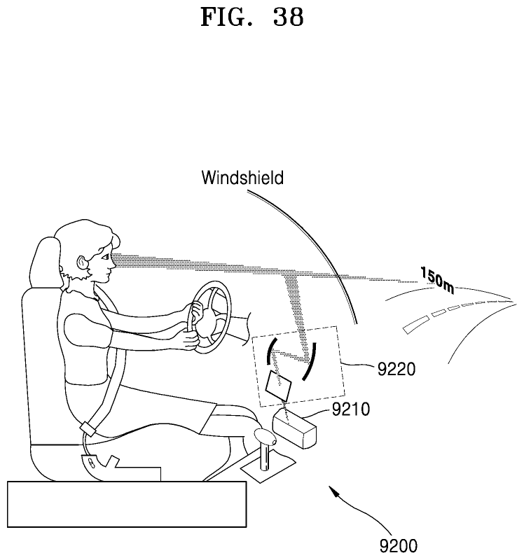

FIG. 38 illustrates an example in which a display apparatus according to an example embodiment is applied to a vehicle display apparatus. The vehicle display apparatus may be a head-up display apparatus 9200 for a vehicle, and may include a display apparatus 9210 provided in an area of the vehicle, and a light path-changing member 9220 for changing light path for a driver to see an image generated by the display apparatus 9210. The display apparatus 9210 may be the display apparatus 200 having the above-described structure.

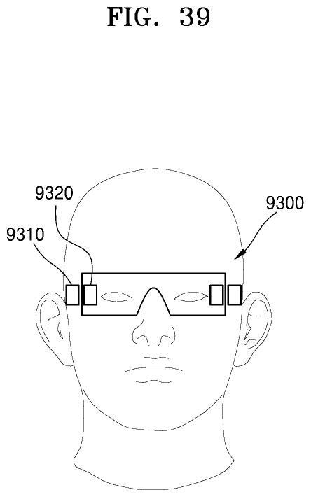

FIG. 39 illustrates an example in which a display apparatus according to an example embodiment is applied to augmented reality glasses or virtual reality glasses. An augmented reality device 9300 in the form of glasses may include a projection system 9310 including a display apparatus for forming an image, and an optical system 9320 for guiding an image from the projection system 9310 to enter a user's eye. The projection system 9310 may include the display apparatus 200 having the above-described structure.

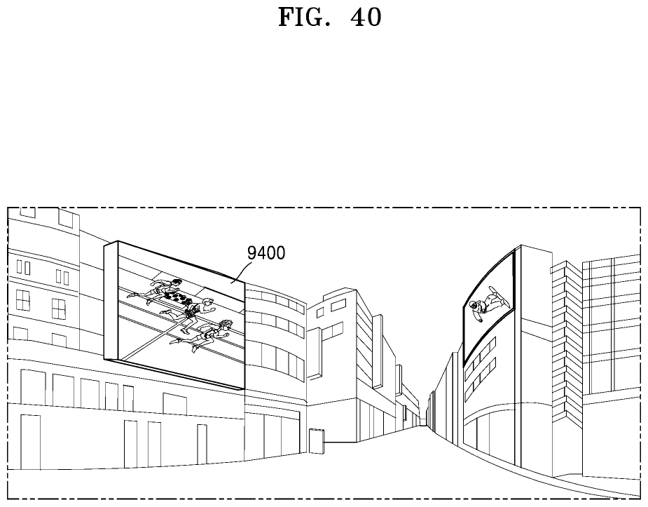

FIG. 40 illustrates an example in which a display apparatus according to an example embodiment is applied to a signage 9400. The signage 9400 may be used for outdoor advertisement using a digital information display and may control advertisement contents and the like through a communication network. The signage 9400 may be implemented, for example, through the electronic device 8201 described with reference to FIG. 36.

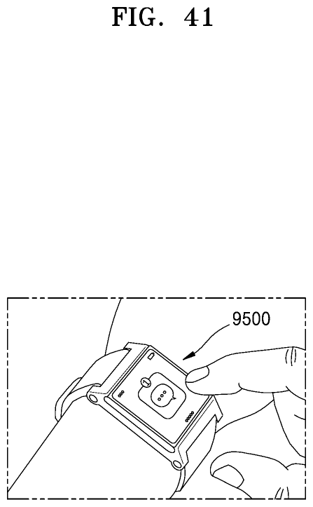

FIG. 41 illustrates an example in which a display apparatus according to an example embodiment is applied to a wearable display 9500. The wearable display 9500 may be the display apparatus 200 having the above-described structure, and may be implemented through the electronic device 8201 described with reference to FIG. 36.

According to various embodiments of the disclosure, a method of manufacturing a nanorod light-emitting diode, the method being capable of securing uniformity of a plurality of nanorod light-emitting diodes while reducing process cost by utilizing a nanometer-scale thin buffer layer, a nanorod light-emitting diode manufactured by the method, and a display apparatus including the nanorod light-emitting diode may be provided.

According to various embodiments of the disclosure, a nanorod light-emitting diode with improved luminous efficiency by having a nanorod shape including a hexagonal pyramid shape, a display apparatus including the nanorod light-emitting diode, and a method of manufacturing the nanorod light-emitting diode may be provided.

According to various embodiments of the disclosure, a method of manufacturing a nanorod light-emitting diode, the method allowing a plurality of nanorod light-emitting diodes to have a uniform shape by causing a meltback etching phenomenon to occur on an etch stop layer including silicon, in a process of manufacturing the plurality of nanorod light-emitting diodes, to form a protrusion in a lower portion of each of the plurality of nanorod light-emitting diodes, a nanorod light-emitting diode manufactured by the method, and a display apparatus including the nanorod light-emitting diode may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A nanorod light-emitting diode comprising:
a first conductivity-type semiconductor layer including a body portion and a top portion provided on the body, the body portion having a cylindrical shape, and the top portion having a hexagonal pyramid shape;
an active layer covering an upper surface of the top portion;
a second conductivity-type semiconductor layer covering an upper surface of the active layer;
an electrode layer covering an upper surface of the second conductivity-type semiconductor layer; and
an insulating layer provided on a side surface of the body portion to cover a first region of the side surface of the body portion and not cover a second region of the side surface of the body portion, the second region being lower than the first region.

2. The nanorod light-emitting diode of claim 1, wherein a height of the second region of the side surface of the body portion is about 20 nm to about 100 nm.

3. The nanorod light-emitting diode of claim 1, wherein a height of the body portion is about 2 μm to about 7 μm.

4. The nanorod light-emitting diode of claim 1, wherein a diameter of the body portion is about 50 nm to about 1000 nm.

5. The nanorod light-emitting diode of claim 1, wherein a first diameter of the body portion at the first region is greater than a second diameter of the body portion at the second region.

6. The nanorod light-emitting diode of claim 1, wherein the insulating layer is in direct contact with the body portion at the first region.

7. A nanorod light-emitting diode comprising:
a first conductivity-type semiconductor layer including a body portion having a cylindrical shape;
an active layer covering an upper surface of the first conductivity-type semiconductor layer and having a hexagonal column shape;
a second conductivity-type semiconductor layer covering an upper surface of the active layer;
an electrode layer covering an upper surface of the second conductivity-type semiconductor layer; and
an insulating layer provided on a side surface of the body portion to cover a first region of the side surface of the body portion and not cover a second region of the side surface of the body portion, the second region being lower than the first region.

8. The nanorod light-emitting diode of claim 7, wherein the insulating layer is in direct contact with the body portion at the first region, a side surface of the active layer, a side surface of the second conductivity-type semiconductor layer, and a side surface of the electrode layer.

9. The nanorod light-emitting diode of claim 7, wherein a height of the second region of the side surface of the body portion is about 20 nm to about 100 nm.

10. A method of manufacturing a nanorod light-emitting diode, the method comprising:
sequentially stacking a buffer layer, an etch stop layer, an oxide layer, and an etch mask layer on a substrate;
sequentially patterning the etch mask layer, the oxide layer, and the etch stop layer to form a plurality of openings that are spaced apart from each other and expose the buffer layer;
forming a first conductivity-type semiconductor material layer by filling the plurality of openings and covering an upper surface of the oxide layer;
forming a plurality of first conductivity-type semiconductor layers by patterning the first conductivity-type semiconductor material layer, each of the plurality of first conductivity-type semiconductor layers having a nanorod shape;
forming a plurality of active layers on the plurality of first conductivity-type semiconductor layers;
forming a plurality of second conductivity-type semiconductor layers on the plurality of active layers;
forming a plurality of electrode layers on the plurality of second conductivity-type semiconductor layers;
removing the oxide layer;
forming a plurality of insulating material layers on upper surfaces of the plurality of electrode layers and side surfaces of the plurality of first conductivity-type semiconductor layers;
forming a plurality of insulating layers surrounding the side surfaces of the plurality of first conductivity-type semiconductor layers by patterning the plurality of insulating material layers to expose the upper surfaces of the plurality of electrode layers; and
separating the plurality of first conductivity-type semiconductor layers from the buffer layer.

11. The method of claim 11, wherein the buffer layer has a thickness of about 5 nm to about 200 nm.

12. The method of claim 11, wherein the buffer layer comprises aluminum nitride.

13. The method of claim 11, wherein the buffer layer has a crystal orientation in a (002) direction.

14. The method of claim 11, wherein the etch stop layer comprises one of amorphous silicon and silicon oxide.

15. The method of claim 11, wherein the etch stop layer has a thickness of about 20 nm to about 100 nm.

16. The method of claim 11, wherein the oxide layer has a thickness of about 2 μm to about 6 μm.

17. The method of claim 15, wherein the first conductivity-type semiconductor material layer comprises gallium, and
wherein, in the forming of the plurality of first conductivity-type semiconductor layers, the first conductive-type semiconductor material layer is formed at a process temperature of about 1100° C. to about 1500° C. such that a first diameter of a central region of each of the plurality of first conductivity-type semiconductor layers is greater than a second diameter of a lower region of each of the plurality of first conductivity-type semiconductor layers, the central region being surrounded by the oxide layer and the lower region being adjacent to the etch stop layer.

18. The method of claim 11, wherein, in the forming of the plurality of first conductivity-type semiconductor layers, the plurality of first conductivity-type semiconductor layers are formed such that upper surfaces of the plurality of first conductivity-type semiconductor layers are higher than the upper surface of the oxide layer with respect to a reference plane parallel to the upper surface of the oxide layer.

19. A method of manufacturing a nanorod light-emitting diode, the method comprising:
sequentially stacking a buffer layer, an etch stop layer, an oxide layer, and an etch mask layer on a substrate;
sequentially patterning the etch mask layer, the oxide layer, and the etch stop layer to form a plurality of openings that are spaced apart from each other and expose the buffer layer;
forming a first conductivity-type semiconductor material layer by filling the plurality of openings and covering an upper surface of the oxide layer;
forming a plurality of first conductivity-type semiconductor layers by patterning the first conductivity-type semiconductor material layer, each of the plurality of first conductivity-type semiconductor layers having a nanorod shape;
removing the oxide layer;
forming a plurality of active layers on the plurality of first conductivity-type semiconductor layers;
forming a plurality of second conductivity-type semiconductor layers on the plurality of active layers;
forming a plurality of electrode layers on the plurality of second conductivity-type semiconductor layers;
forming a plurality of insulating material layers on the plurality of electrode layers;
forming a plurality of insulating layers surrounding side surfaces of the plurality of electrode layers by patterning the plurality of insulating material layers to expose upper surfaces of the plurality of electrode layers; and
separating the plurality of first conductivity-type semiconductor layers from the buffer layer.

20. A display apparatus comprising:
a pixel array comprising a plurality of nanorod light-emitting diodes arranged in two dimensions;
a scan driver configured to apply a scan signal to the pixel array;
a data driver configured to apply a data signal to the pixel array; and
a processor configured to control operations of the scan driver and the data driver,
wherein each of the plurality of nanorod light-emitting diodes comprises:
a first conductivity-type semiconductor layer including a body portion having a cylindrical shape;
an active layer covering an upper surface of the first conductivity-type semiconductor layer and having a hexagonal column shape;
a second conductivity-type semiconductor layer covering an upper surface of the active layer;
an electrode layer covering an upper surface of the second conductivity-type semiconductor layer; and
an insulating layer provided on a side surface of the body portion to cover a first region of the side surface of the body portion and not cover a second region of the side surface of the body portion, the second region being lower than the first region.
